(19) United States
(12) Patent Application Publication
(10) Pub. No.: US 2024/0250227 A1
(43) Pub. Date: Jul. 25, 2024

(54) DISPLAY DEVICE

(71) Applicant: Samsung Display Co., LTD., Yongin-si (KR)

(72) Inventors: Do Yeong PARK, Yongin-si (KR); Ki Hyun PYO, Yongin-si (KR); Sung Chul HONG, Yongin-si (KR)

(21) Appl. No.: 18/395,176

(22) Filed: Dec. 22, 2023

(30) Foreign Application Priority Data
Jan. 25, 2023 (KR) 10-2023-0009587

(51) Int. Cl. H01L 33/62; G09G 3/32; H01L 25/16; H01L 27/12; H01L 33/48

(52) U.S. Cl. CPC H01L 33/62; G09G 3/32; H01L 25/167; H01L 27/124; H01L 33/483; G09G 2300/0819; G09G 2300/0842; G09G 2300/0861

(57) ABSTRACT

A display device includes signal lines, auxiliary electrodes on the signal lines, bank patterns on the auxiliary electrodes and spaced from each other, alignment electrodes on the bank patterns and spaced from each other, and light emitting elements between the bank patterns. The alignment electrodes are electrically connected to the auxiliary electrodes through a contact hole passing through the bank patterns, respectively, and the auxiliary electrodes and the alignment electrodes are insulated from the signal lines.

### CROSS-REFERENCE TO RELATED APPLICATION

This application claims priority to and the benefit of Korean Patent Application No. 10-2023-0009587, filed on Jan. 25, 2023, the entire content of which is incorporated by reference herein.

### BACKGROUND

### 1. Field

The present disclosure relates to a display device.

### 2. Description of the Related Art

Recently, as interest in an information display is increasing, research and development for a display device are continuously being conducted.

### SUMMARY

Aspects and features of embodiments of the present disclosure are to provide a display device capable of improving an alignment degree of light emitting elements.

Aspects and features of the present disclosure are not limited to the above-described aspects and features, and other technical aspects and features which are not described will be clearly understood by those skilled in the art from the following description.

According to one or more embodiments of the present disclosure, a display device includes signal lines, auxiliary electrodes on the signal lines, bank patterns on the auxiliary electrodes and spaced from each other, alignment electrodes on the bank patterns and spaced from each other, and light emitting elements between the bank patterns. The alignment electrodes are electrically connected to the auxiliary electrodes through a contact hole passing through the bank patterns, respectively, and the auxiliary electrodes and the alignment electrodes are insulated from the signal lines.

The display device may further include a first insulating layer between the auxiliary electrodes and the bank patterns.

The bank patterns and the first insulating layer may have a same shape on a plane.

The display device may further include a second insulating layer between the alignment electrodes and the light emitting elements.

The display device may further include a hole passing through the first insulating layer and the second insulating layer.

The display device may further include an emission area, the light emitting elements being located in the emission area, a non-emission area surrounding the emission area, and a bank in the non-emission area and including an opening exposing the emission area.

The auxiliary electrodes may overlap the bank.

The alignment electrodes may include a first area overlapping the auxiliary electrodes and a second area crossing the auxiliary electrodes in the non-emission area.

The display device may further include connection electrodes on the light emitting elements and electrically connected to the signal lines.

The connection electrodes may include a first connection electrode contacting a first end of the light emitting elements and a second connection electrode contacting a second end of the light emitting elements.

According to one or more embodiments of the present disclosure for solving the above-described object, a display device includes signal lines, auxiliary electrodes extending in a first direction on the signal lines, alignment electrodes including a first area overlapping the auxiliary electrodes and extending in the first direction and a second area extending in a second direction crossing the first direction, and light emitting elements between the alignment electrodes. The second area of the alignment electrodes contacts the auxiliary electrodes through a contact hole, and the auxiliary electrodes and the alignment electrodes are insulated from the signal lines.

The display device may further include an emission area, the light emitting elements being located in the emission area, a non-emission area surrounding the emission area, and a bank in the non-emission area and including an opening exposing the emission area.

The auxiliary electrodes may overlap the bank.

The first area of the alignment electrodes may overlap the emission area.

The second area of the alignment electrodes may be in the non-emission area.

The display device may further include bank patterns located between the auxiliary electrodes and the alignment electrodes.

The bank patterns may extend in the first direction.

The contact hole may be formed in the bank patterns.

The display device may further include connection electrodes on the light emitting elements and electrically connected to the signal lines.

The connection electrodes may include a first connection electrode contacting a first end of the light emitting elements and a second connection electrode contacting a second end of the light emitting elements.

Details of other embodiments are included in the detailed description and drawings.

According to the above-described embodiment, because the alignment electrodes are insulated from the signal lines, an influence of an electric field due to the signal lines may be reduced or minimized when aligning the light emitting elements. In addition, because a voltage drop of the alignment electrodes may be reduced or minimized by forming the alignment electrodes in a mesh structure and additionally using the auxiliary electrodes, an alignment degree of the light emitting elements may be improved.

An effect according to embodiments is not limited by the contents illustrated above, and more various effects are included in the present specification.

### BRIEF DESCRIPTION OF THE DRAWINGS

The above and other features of the present disclosure will become more apparent by describing in further detail embodiments thereof with reference to the accompanying drawings, in which:

FIG. 1 is a perspective view illustrating a light emitting element according to one or more embodiments;

FIG. 2 is a cross-sectional view illustrating a light emitting element according to one or more embodiments;

FIG. 3 is a plan view illustrating a display device according to one or more embodiments;

FIGS. 4 to 6 are circuit diagrams illustrating a pixel according to one or more embodiments;

FIG. 7 is a plan view illustrating a pixel circuit according to one or more embodiments;

FIGS. 8 and 9 are plan views illustrating first to third pixels according to one or more embodiments;

FIGS. 10 and 11 are plan views illustrating a pixel according to one or embodiments;

FIGS. 12 and 13 are cross-sectional views taken along the line A-A′ of FIG. 10;

FIG. 14 is a cross-sectional view taken along the line B-B′ of FIG. 10;

FIG. 15 is a cross-sectional view taken along the line C-C′ of FIG. 11;

FIG. 16 is a cross-sectional view illustrating first to third pixels according to one or more embodiments; and

FIG. 17 is a cross-sectional view of a pixel according to one or more embodiments.

### DETAILED DESCRIPTION

The aspects and features of the present disclosure and a method of achieving them will become apparent with reference to the embodiments described in detail below together with the accompanying drawings. However, the present disclosure is not limited to the embodiments disclosed below, and may be implemented in various different forms. The present embodiments are provided so that the present disclosure will be thorough and complete and those skilled in the art to which the present disclosure pertains can fully understand the scope of the present disclosure. The present disclosure is defined by the scope of the claims and their equivalents.

The terms used in the present disclosure are for describing embodiments and is not intended to limit the present disclosure. In the present disclosure, the singular form also includes the plural form unless otherwise specified. The term “comprises” and/or “comprising” does not exclude presence or addition of one or more other components, steps, operations, and/or elements to the described component, step, operation, and/or element.

The term “coupling” or “connection” may collectively mean a physical and/or electrical coupling or connection. This may collectively mean a direct or indirect coupling or connection and an integral or non-integral coupling or connection.

A case in which an element or a layer is referred to as “on” another element or layer includes a case in which another layer or another element is disposed directly on the other element or between the other layers. The same reference numerals denote to the same components throughout the present disclosure.

Although a first, a second, and the like are used to describe various components, these components are not limited by these terms. These terms are used only to distinguish one component from another component. Therefore, a first component described below may be a second component within the technical spirit of the present disclosure.

Hereinafter, embodiments of the present disclosure are described in detail with reference to the accompanying drawings.

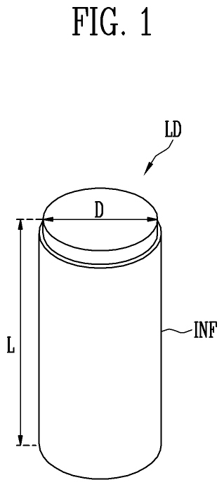

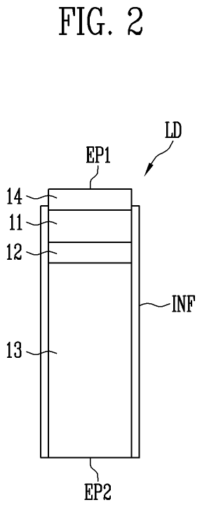

FIG. 1 is a perspective view illustrating a light emitting element according to one or more embodiments. FIG. 2 is a cross-sectional view illustrating a light emitting element according to one or more embodiments. FIGS. 1 and 2 show a column shape light emitting element LD, but a type and/or a shape of the light emitting element LD are/is not necessarily limited thereto.

Referring to FIGS. 1 and 2, the light emitting element LD may include a first semiconductor layer 11, an active layer 12, a second semiconductor layer 13, and/or an electrode layer 14.

The light emitting element LD may be formed in a column shape extending along one direction. The light emitting element LD may have a first end EP1 and a second end EP2. One of the first and second semiconductor layers 11 and 13 may be disposed at the first end EP1 of the light emitting element LD. The other one of the first and second semiconductor layers 11 and 13 may be disposed at the second end EP2 of the light emitting element LD. For example, the first semiconductor layer 11 may be disposed at the first end EP1 of the light emitting element LD, and the second semiconductor layer 13 may be disposed at the second end EP2 of the light emitting element LD.

According to one or more embodiments, the light emitting element LD may be a light emitting element manufactured in a column shape through an etching method or the like. In the present disclosure, the column shape includes a rod-like shape or a bar-like shape of which an aspect ratio is greater than 1, such as a circular column or a polygonal column, and the shape of the cross-section thereof is not limited.

The light emitting element LD may have a size as small as a nanometer scale to a micrometer scale. For example, each light emitting element LD may have a diameter D (or width) and/or a length L of a nanometer scale to micrometer scale range. However, a size of the light emitting element LD is not necessarily limited thereto, and the size of the light emitting element LD may be variously changed according to a design condition of various devices using a light emitting device using the light emitting element LD as a light source, for example, a display device or the like. The first semiconductor layer 11 may be a semiconductor layer of a first

conductivity type. For example, the first semiconductor layer 11 may include a p-type semiconductor layer. For example, the first semiconductor layer 11 may include at least one semiconductor material selected from among InAlGaN, GaN, AIGaN, InGaN, and AlN, and may include a p-type semiconductor layer doped with a first conductivity type dopant such as Mg. However, a material configuring the first semiconductor layer 11 is not necessarily limited thereto, and various other materials may configure the first semiconductor layer 11.

The active layer 12 may be disposed between the first semiconductor layer 11 and the second semiconductor layer 13. The active layer 12 may include one or more of a single well structure, a multi well structure, a single quantum well structure, a multi quantum well (MQW) structure, a quantum dot structure, or a quantum wire structure, but is not necessarily limited thereto. The active layer 12 may include one or more selected from among GaN, InGaN, InAlGaN, AIGaN, and AlN, and various other materials may configure the active layer 12.

When a voltage equal to or greater than a threshold voltage is applied between both ends of the light emitting element LD, an electron-hole pair is combined in the active layer 12 and thus the light emitting element LD emits light. By controlling emission of the light emitting element LD using such a principle, the light emitting element LD may be used as a light source of various light emitting devices including a pixel of a display device.

The second semiconductor layer 13 may be disposed on the active layer 12 and may include a semiconductor layer of a type different from that of the first semiconductor layer 11. The second semiconductor layer 13 may include an n-type semiconductor layer. For example, the second semiconductor layer 13 may include one or more semiconductor material selected from among InAlGaN, GaN, AIGaN, InGaN, and AlN, and may include an n-type semiconductor layer doped with a second conductivity type dopant such as Si, Ge, and Sn. However, a material configuring the second semiconductor layer 13 is not necessarily limited thereto, and various other materials may configure the second semiconductor layer 13.

The electrode layer 14 may be disposed on the first end EP1 and/or the second end EP2 of the light emitting element LD. FIG. 2 illustrates a case in which the electrode layer 14 is formed on the first semiconductor layer 11, but the present disclosure is not necessarily limited thereto. For example, a separate contact electrode may be further disposed on the second semiconductor layer 13.

The electrode layer 14 may include a transparent metal or a transparent metal oxide. For example, the electrode layer 14 may include at least one selected from among indium tin oxide (ITO), indium zinc oxide (IZO), and zinc tin oxide (ZTO), but is not necessarily limited thereto. As described above, when the electrode layer 14 is formed of the transparent metal or the transparent metal oxide, light generated in the active layer 12 of the light emitting element LD may pass through the electrode layer 14 and may be emitted to an outside of the light emitting element LD.

An insulating film INF may be provided on a surface (e.g., an outer peripheral or circumferential surface) of the light emitting element LD. The insulating film INF may be directly disposed on a surface (e.g., an outer peripheral or circumferential surface) of the first semiconductor layer 11, the active layer 12, the second semiconductor layer 13, and/or the electrode layer 14. The insulating film INF may expose the first and second ends EP1 and EP2 of the light emitting element LD having different polarities. According to one or more embodiments, the insulating film INF may expose a side portion of the electrode layer 14 and/or the second semiconductor layer 13 adjacent to the first and second ends EP1 and EP2 of the light emitting element LD.

The insulating film INF may prevent an electrical short that may occur when the active layer 12 comes into contact with a conductive material except for the first and second semiconductor layers 11 and 13. The insulating film INF may reduce or minimize a surface defect of the light emitting elements LD, thereby improving lifespan and emission efficiency of the light emitting elements LD.

The insulating film INF may include at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx). For example, the insulating film INF may be configured as double layers, and each layer configuring the double layers may include different materials. For example, the insulating film INF may be configured as double layers configured of aluminum oxide (AlOx) and silicon oxide (SiOx), but is not necessarily limited thereto. According to one or more embodiments, the insulating film INF may be omitted.

A light emitting device including the light emitting element LD described above may be used in various types of devices that require a light source, including a display device. For example, the light emitting elements LD may be disposed in each pixel of a display panel, and the light emitting elements LD may be used as a light source of each pixel. However, an application field of the light emitting element LD is not limited to the above-described example. For example, the light emitting element LD may also be used in other types of devices that require a light source, such as a lighting device.

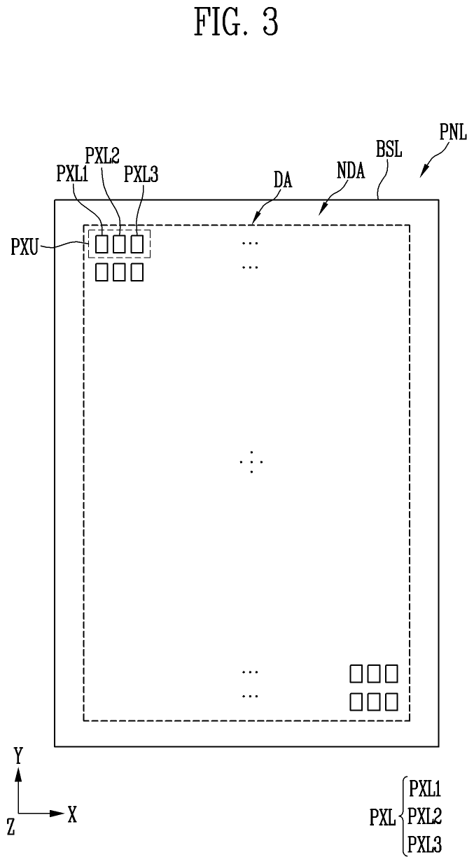

FIG. 3 is a plan view illustrating a display device according to one or more embodiments.

In FIG. 3, as an example of an electronic device that may use the light emitting element LD described in the embodiments of FIGS. 1 and 2 as a light source, a display device, particularly, a display panel PNL provided in the display device is shown.

For convenience of description, a structure of the display panel PNL is briefly shown based on a display area DA in FIG. 3. However, according to one or more embodiments, at least one driving circuit unit (for example, at least one of a scan driver and a data driver), lines and/or pads, may be further disposed on the display panel PNL.

Referring to FIG. 3, the display panel PNL and a base layer BSL for forming the same may include the display area DA for displaying an image and a non-display area NDA except for the display area DA around an edge or periphery of the display area DA. The display area DA may configure a screen on which the image is displayed, and the non-display area NDA may be an area except for the display area DA.

A pixel unit PXU may be disposed in the display area DA. The pixel unit PXU may include a first pixel PXL1, a second pixel PXL2, and/or a third pixel PXL3. Hereinafter, when at least one pixel from among the first pixel PXL1, the second pixel PXL2, and the third pixel PXL3 is arbitrarily referred to, or when two or more types of pixels are collectively referred to, the at least one pixel or the two or more types of pixels are referred to as a “pixel PXL” or “pixels PXL”.

The pixels PXL may be regularly arranged according to a stripe or PENTILE® arrangement structure, but the present disclosure is not limited thereto. p This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. However, an arrangement structure of the pixels PXL is not necessarily limited thereto, and the pixels PXL may be arranged in the display area DA in various structures and/or methods.

According to one or more embodiments, two or more types of pixels PXL emitting light of different colors may be disposed in the display area DA. For example, in the display area DA, the first pixels PXL1 emitting light of a first color, the second pixels PXL2 emitting light of a second color, and the third pixels PXL3 emitting light of a third color may be arranged. At least one of the first to third pixels PXL1, PXL2, and PXL3 disposed to be adjacent to each other may configure one pixel unit PXU capable of emitting light of various colors. For example, each of the first to third pixels PXL1, PXL2, and PXL3 may be a pixel emitting light of a desired color (e.g., a predetermined color). According to one or more embodiments, the first pixel PXL1 may be a red pixel emitting red light, the second pixel PXL2 may be a green pixel emitting green light, and the third pixel PXL3 may be a blue pixel emitting blue light, but the present disclosure is not limited thereto.

In one or more embodiments, the first pixel PXL1, the second pixel PXL2, and the third pixel PXL3 may include light emitting elements that emit light of the same color, and may include a color conversion layer and/or a color filter layer of different colors disposed on the respective light emitting elements, to emit light of the first color, the second color, and the third color, respectively. In one or more embodiments, the first pixel PXL1, the second pixel PXL2, and the third pixel PXL3 may include a light emitting element of the first color, a light emitting element of the second color, and a light emitting element of the third color as a light source, to emit light of the first color, the second color, and the third color, respectively. However, the color, type, number, and/or the like of the pixels PXL configuring each pixel unit PXU are not particularly limited. That is, the color of light emitted by each pixel PXL may be variously changed.

The pixel PXL may include at least one light source driven by a control signal (for example, a scan signal and a data signal) and/or power (for example, first driving power and second driving power). In one or more embodiments, the light source may include at least one light emitting element LD according to one of the embodiments of FIGS. 1 and 2, for example, an ultra-small column shape light emitting elements LD having a size as small as a nanometer scale to a micrometer scale. However, the present disclosure is not necessarily limited thereto, and various types of light emitting elements LD may be used as the light source of the pixel PXL.

In one or more embodiments, each pixel PXL may be configured as an active pixel. However, a type, a structure, and/or a driving method of the pixel PXL applicable to the display device are/is not particularly limited. For example, each pixel PXL may be configured as a pixel of a passive or active light emitting display device of various structures and/or driving methods.

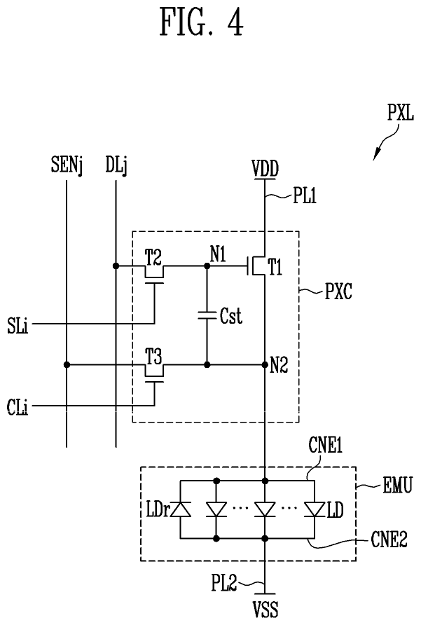

FIGS. 4 to 6 are circuit diagrams illustrating a pixel according to one or more embodiments.

The pixel PXL shown in FIGS. 4 to 6 may be one of the first pixel PXL1, the second pixel PXL2, and the third pixel PXL3 provided in the display panel PNL of FIG. 3. The first pixel PXL1, the second pixel PXL2, and the third pixel PXL3 may have structures substantially identical to or similar to each other.

Referring to FIGS. 4 to 6, the pixel PXL may include a light emitting unit EMU generating light of a luminance corresponding to the data signal and a pixel circuit PXC for driving the light emitting unit EMU.

The light emitting unit EMU may include light emitting elements LD connected in parallel between a first power line PL1 and a second power line PL2. The first power line PL1 may be connected to first driving power VDD, and thus a voltage of the first driving power VDD may be applied to the first power line PL1.

The second power line PL2 may be connected to second driving power VSS, and thus a voltage of the second driving power VSS may be applied to the second power line PL2.

The light emitting unit EMU may include a first pixel electrode CNE1 connected to the first driving power VDD through the pixel circuit PXC and the first power line PL1, a second pixel electrode CNE2 connected to the second driving power VSS through the second power line PL2, and light emitting elements LD connected in parallel in the same direction between the first pixel electrode CNE1 and the second pixel electrode CNE2. In one or more embodiments, the first pixel electrode CNE1 may be an anode (or an anode electrode), and the second pixel electrode CNE2 may be a cathode (or a cathode electrode).

The light emitting elements LD included in the light emitting unit EMU may include a first end connected to the first driving power VDD through the first pixel electrode CNE1 and a second end connected to the second driving power VSS through the second pixel electrode CNE2. The first driving power VDD and the second driving power VSS may have different potentials. For example, the first driving power VDD may be set as high potential power, and the second driving power VSS may be set as low potential power. At this time, a potential difference between the first driving power VDD and the second driving power VSS may be set as a threshold voltage or more of the light emitting elements LD during an emission period of each pixel PXL.

As described above, the respective light emitting elements LD connected in parallel in the same direction (for example, a forward direction) between the first pixel electrode CNE1 and the second pixel electrode CNE2 to which the voltages of the different power are supplied may configure respective effective light sources.

The light emitting elements LD of the light emitting unit EMU may emit light with a luminance corresponding to a driving current supplied through a corresponding pixel circuit PXC. For example, the pixel circuit PXC may supply a driving current corresponding to a grayscale value of corresponding frame data of the pixel circuit PXC to the light emitting unit EMU during each frame period. The driving current supplied to the light emitting unit EMU may be divided and may flow to each of the light emitting elements LD. Therefore, each of the light emitting elements LD may emit light with a luminance corresponding to the current flowing through the light emitting element LD, and thus the light emitting unit EMU may emit light of the luminance corresponding to the driving current.

In the above-described embodiment, an embodiment in which the both ends of the light emitting elements LD are connected in the same direction between the first and second driving power VDD and VSS is described, but the present disclosure is not limited thereto. According to one or more embodiments, the light emitting unit EMU may further include at least one ineffective light source, for example, a reverse light emitting element LDr, in addition to the light emitting elements LD configuring each effective light source. The reverse light emitting element LDr may be connected in parallel between the first and second pixel electrodes CNE1 and CNE2 together with the light emitting elements LD configuring the effective light sources, and may be connected between the first and second pixel electrodes CNE1 and CNE2 in a direction opposite to the light emitting elements LD. The reverse light emitting element LDr maintains an inactivation state even though a driving voltage (e.g., a predetermined driving voltage, for example, a driving voltage of a forward direction) is applied between the first and second pixel electrodes CNE1 and CNE2, and thus a current substantially may not flow through the reverse light emitting element LDr.

The pixel circuit PXC may be connected to a scan line SLi (or a first gate line) and a data line DLj of the pixel PXL. The pixel circuit PXC may be connected to a control line CLi (or a second gate line) and a sensing line SENj (or a readout line) of the pixel PXL. For example, when the pixel PXL is disposed in an i-th row and a j-th column of the display area DA, the pixel circuit PXC of the pixel PXL may be connected to the i-th scan line SLi, the j-th data line DLj, the i-th control line CLi, and the j-th sensing line SENj of the display area DA. According to one or more embodiments, the control line CLi may be connected to the scan line SLi.

The pixel circuit PXC may include transistors T1 to T3 and a storage capacitor Cst (or a capacitor).

The first transistor T1 may be a driving transistor for controlling the driving current applied to the light emitting unit EMU, and may be connected between the first driving power VDD and the light emitting unit EMU. Specifically, a first terminal (or a first transistor electrode) of the first transistor T1 may be electrically connected to the first driving power VDD through the first power line PL1, a second terminal (or a second transistor electrode) of the first transistor T1 may be electrically connected to a second node N2, and a gate electrode of the first transistor T1 may be electrically connected to a first node N1. The first transistor T1 may control an amount of the driving current applied from the first driving power VDD to the light emitting unit EMU through the second node N2, according to a voltage applied to the first node N1. In one or more embodiments, the first terminal of the first transistor T1 may be a drain electrode, and the second terminal of the first transistor T1 may be a source electrode, but the present disclosure is not limited thereto. According to one or more embodiments, the first terminal may be a source electrode and the second terminal may be a drain electrode.

The second transistor T2 may be a switching transistor that selects the pixel PXL in response to a scan signal and activates the pixel PXL, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 may be different terminals. For example, when the first terminal is a drain electrode, the second terminal may be a source electrode.

The second transistor T2 may be turned on when a scan signal of a gate-on voltage (for example, a high level voltage) is supplied from the scan line SLi, to electrically connect the data line DLj and the first node N1. The first node N1 may be a point where the second terminal of the second transistor T2 and the gate electrode of the first transistor T1 are connected, and the second transistor T2 may transmit the data signal to the gate electrode of the first transistor Ti.

A first terminal of the third transistor T3 may be connected to the sensing line SENj, a second terminal of the third transistor T3 may be connected to the second terminal of the first transistor T1, and a gate electrode of the third transistor T3 may be connected to the control line CLi. Initialization power may be applied to the sensing line SENj. The third transistor T3 may be an initialization transistor capable of initializing the second node N2, and may be turned on when a sensing control signal is supplied from the control line CLi to transmit a voltage of the initialization power to the second node N2. Accordingly, a second storage electrode of the storage capacitor Cst electrically connected to the second node N2 may be initialized. According to one or more embodiments, as the third transistor T3 may connect the first transistor T1 to the sensing line SENj, a sensing signal may be obtained through the sensing line SENj, and a characteristic of the pixel PXL including a threshold voltage or the like of the first transistor T1 may be detected using the sensing signal. Information on the characteristic of the pixel PXL may be used to convert image data so that a characteristic deviation between the pixels PXL may be compensated.

The storage capacitor Cst may be formed between the first node N1 and the second node N2 or electrically connected between the first node N1 and the second node N2. The storage capacitor Cst may charge a data voltage corresponding to a data signal supplied to the first node N1 during one frame period. Accordingly, the storage capacitor Cst may store a voltage corresponding to a difference between a voltage of the gate electrode of the first transistor T1 and a voltage of the second node N2.

The light emitting unit EMU may be configured to include at least one series stage (or a stage) including light emitting elements LD electrically connected to each other in parallel.

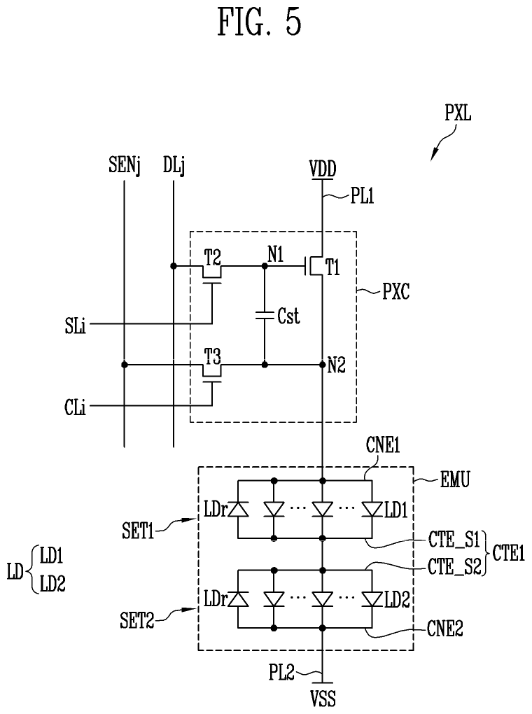

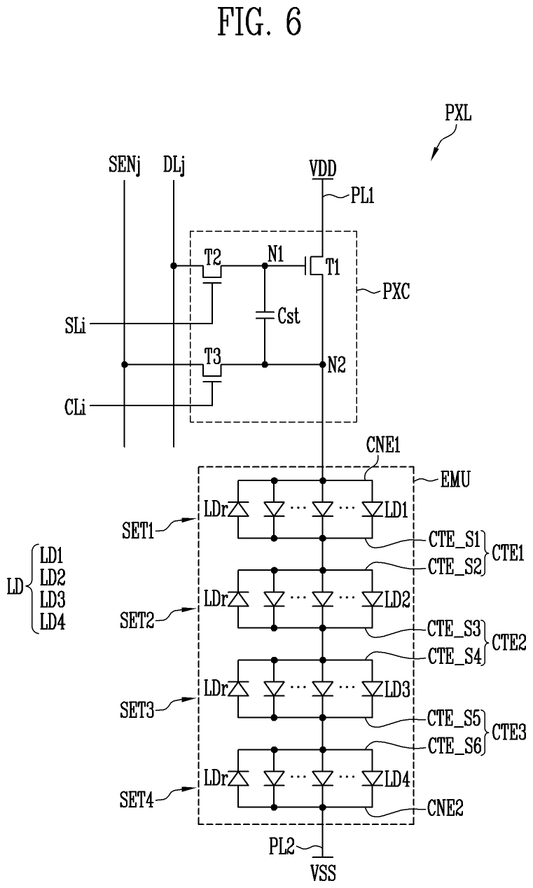

According to one or more embodiments, the light emitting unit EMU may also be configured in a series/parallel mixed structure. For example, as shown in FIG. 5, the light emitting unit EMU may be configured to include a first series stage SET1 and a second series stage SET2. As another example, as shown in FIG. 6, the light emitting unit EMU may also be configured to include a first series stage SET1, a second series stage SET2, a third series stage SET3, and a fourth series stage SET4. The number of series stages included in the light emitting unit EMU may be variously changed, and for example, the light emitting unit EMU may include three or five or more series stages.

Referring to FIG. 5, the light emitting unit EMU may include the first series stage SET1 and the second series stage SET2 sequentially connected between the first driving power VDD and the second driving power VSS. Each of the first series stage SET1 and the second series stage SET2 may include two electrodes CNE1 and CTE_S1, and CTE_S2 and CNE2 configuring an electrode pair of a corresponding series stage, and light emitting elements LD connected in parallel in the same direction between the two electrodes CNE1 and CTE_S1, and CTE_S2 and CNE2.

The first series stage SET1 (or a first stage) may include the first pixel electrode CNE1 and the first sub-intermediate electrode CTE_S1, and may include at least one first light emitting element LD1 connected between the first pixel electrode CNE1 and the first sub-intermediate electrode CTE_S1. The first series stage SET1 may further include a reverse light emitting element LDr connected in an opposite direction to the first light emitting element LD1 between the first pixel electrode CNE1 and the first sub-intermediate electrode CTE_S1.

The second series stage SET2 (or a second stage) may include the second sub-intermediate electrode CTE_S2 and the second pixel electrode CNE2, and may include at least one second light emitting element LD2 connected between the second sub-intermediate electrode CTE_S2 and the second pixel electrode CNE2. The second series stage SET2 may further include a reverse light emitting element LDr connected in an opposite direction to the second light emitting element LD2 between the second sub-intermediate electrode CTE_S2 and the second pixel electrode CNE2.

The first sub-intermediate electrode CTE_S1 of the first series stage SET1 and the second sub-intermediate electrode CTE_S2 of the second series stage may be integrally provided and connected to each other. For example, the first sub-intermediate electrode CTE_S1 and the second sub-intermediate electrode CTE_S2 may configure a first intermediate electrode CTE1 electrically connecting the successive first series stage SET1 and the second series stage SET2. When the first sub-intermediate electrode CTE_S1 and the second sub-intermediate electrode CTE_S2 are integrally provided, the first sub-intermediate electrode CTE_S1 and the second sub-intermediate-electrode CTE_S2 may be different one areas of the first intermediate electrode CTE1. The terms of the pixel electrode and the intermediate electrode are only expressions for distinguishing electrodes, and corresponding configurations (that is, electrodes) are not limited by the terms.

Referring to FIG. 6, the light emitting unit EMU may include the first series stage SET1, the second series stage SET2, the third series stage SET3, and the fourth series stage SET4 sequentially connected between the first driving power VDD and the second driving power VSS.

The first series stage SET1 of FIG. 6 may be substantially the same as the first series stage SET1 of FIG. 5.

The second series stage SET2 may include at least one second light emitting element LD2 connected between a second sub-intermediate electrode CTE_S2 and a third sub-intermediate electrode CTE_S3. The third series stage SET3 may include at least one third light emitting element LD3 connected between a fourth sub-intermediate electrode CTE_S4 and a fifth sub-intermediate electrode CTE_S5. The fourth series stage SET4 may include at least one fourth light emitting element LD4 connected between a sixth sub-intermediate electrode CTE_S6 and the second pixel electrode CNE2. The third sub-intermediate electrode CTE_S3 and the fourth sub-intermediate electrode CTE_S4 may be integrally provided and connected to each other, and may configure a second intermediate electrode CTE2. The fifth sub-intermediate electrode CTE_S5 and the sixth sub-intermediate electrode CTE_S6 may be integrally provided and connected to each other, and may configure a third intermediate electrode CTE3.

As described above, the light emitting unit EMU of the pixel PXL including the series stages SET1, SET2, SET3, and SET4 (or the light emitting elements LD) connected in the series/parallel mixed structure may control a driving current/voltage condition according to a specification or a requirement of a product to which it is applied.

In particular, the light emitting unit EMU of the pixel PXL including the series stages SET1, SET2, SET3, and SET4 may reduce the driving current compared to a light emitting unit of a structure in which the light emitting elements LD are connected only in parallel. The light emitting unit EMU of the pixel PXL including the series stages SET1, SET2, SET3, and SET4 may emit light with a higher luminance with respect to the same driving current.

The light emitting unit EMU of the pixel PXL including the series stages SET1, SET2, SET3, and SET4 may reduce the driving voltage applied between both ends of the light emitting unit EMU compared to a light emitting unit of a structure in which the same number of all light emitting elements LD are connected in series.

In one or more embodiments, in FIGS. 4 to 6, all transistors T1, T2, and T3 included in the pixel circuit PXC are n-type transistors, but are not necessarily limited thereto. For example, at least one of the transistors T1, T2, and T3 may be changed to a p-type transistor.

A structure and a driving method of the pixel PXL may be variously changed. For example, the pixel circuit PXC may be configured of a pixel circuit of various structures and/or driving methods, in addition to the embodiments shown in FIGS. 4 to 6.

For example, the pixel circuit PXC may not include the third transistor T3. The pixel circuit PXC may further include other circuit elements such as a compensation transistor for compensating for the threshold voltage or the like of the first transistor T1, an initialization transistor for initializing a voltage of the first node N1 and/or the first pixel electrode CNE1, an emission control transistor for controlling a period in which the driving current is supplied to the light emitting unit EMU, a boosting capacitor for boosting the voltage of the first node N1, and/or the like.

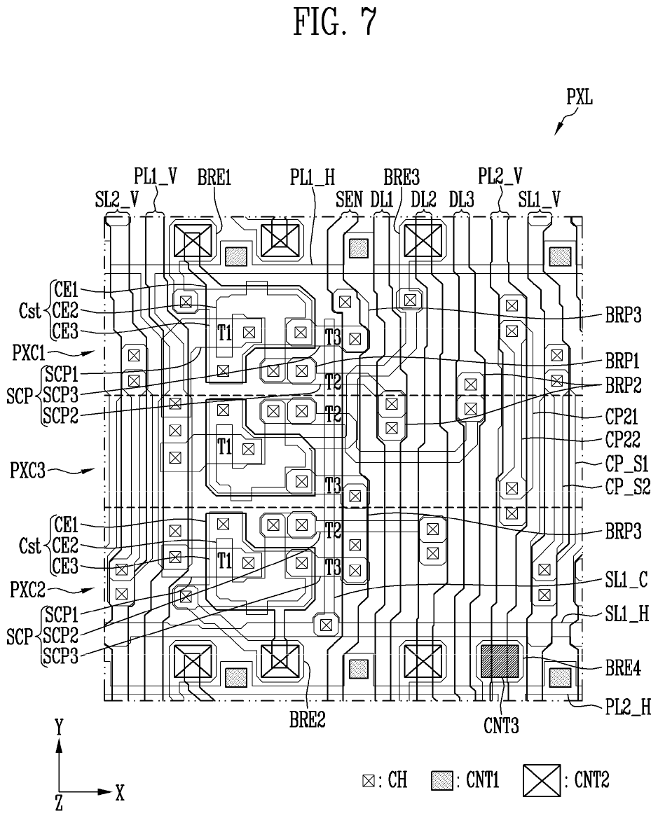

FIG. 7 is a plan view illustrating a pixel circuit according to one or more embodiments.

Referring to FIG. 7, the pixel PXL may include a first pixel circuit PXC1 for the first pixel PXL1 (refer to FIG. 3), a second pixel circuit PXC2 for the second pixel PXL2 (refer to FIG. 3), and a third pixel circuit PXC3 for the third pixel PXL3 (refer to FIG. 3). The first pixel circuit PXC1 may have a structure symmetrical to the third pixel circuit PXC3 in a second direction (Y-axis direction), and the second pixel circuit PXC2 may have a structure substantially identical to or similar to that of the third pixel circuit PXC3. Therefore, a common configuration of the pixel circuits PXC1, PXC2, and PXC3 (or the pixels PXL1, PXL2, and PXL3) is described based on the third pixel circuit PXC3 (or the third pixel PXL3), and a duplicate description is not to be repeated.

Signal lines, for example, each of a first vertical power line PL1_V, a sensing line SEN, a first data line DL1, a second data line DL2, a third data line DL3, a second vertical power line PL2_V, and a first vertical scan line SL1_V may generally extend in the second direction (Y-axis direction) and may be arranged along a first direction (X-axis direction). The second vertical scan line SL2_V may correspond to the first vertical scan line SL1_V. For example, the first vertical scan line SL1_V may be a configuration for the pixel PXL, and the second vertical scan line SL2_V may be a configuration for a pixel adjacent to the pixel PXL in the first direction (X-axis direction) (or in a direction opposite to the first direction (X-axis direction)). Similar to the first and second vertical scan lines SL1_V and SL2_V, the first vertical power line PL1_V, the sensing line SEN, the first data line DL1, the second data line DL2, the third data line, DL3, and the second vertical power line PL2_V may be repeatedly arranged along the first direction (X-axis direction) for other pixels included in the same row as the pixel PXL. The first vertical power line PL1_V, the sensing line SEN, the first data line DL1, the second data line DL2, the third data line DL3, the second vertical power line PL2_V, and the first vertical scan line SL1_V may be formed of a first conductive layer.

The first horizontal power line PL1_H, the first horizontal scan line SL1_H, and the second horizontal power line PL2_H may generally extend in the first direction (X-axis direction) and may be arranged along in the second direction (Y-axis direction). The first horizontal power line PL1_H, the first horizontal scan line SL1_H, and the second horizontal power line PL2_H may be formed of a third conductive layer.

The first vertical scan line SL1_V and the first horizontal scan line SL1_H may configure one scan line (for example, the scan line SLi of FIG. 4). The first vertical scan line SL1_V may be omitted according to a disposition position of the scan driver that supplies the scan signal to the scan line. The first vertical power line PL1_V and the first horizontal power line PL1_H may configure the first power line PL1 (refer to FIG. 4), and the second vertical power line PL2_V and the second horizontal power line PL2_H may configure the second power line PL2 (refer to FIG. 4). The first power line PL1 may have a mesh structure throughout the display panel PNL (refer to FIG. 3) through the first vertical power line PL1_V and the first horizontal power line PL1_H, and similarly, the second power line PL2 may have a mesh structure throughout the display panel PNL (refer to FIG. 3) through the second vertical power line PL2_V and the second horizontal power line PL2_H.

A twenty-first connection pattern CP21 and a twenty-second connection pattern CP22 may overlap the second vertical power line PL2_V and may be connected to the second vertical power line PL2_V through a contact hole CH. Similarly, a first sub-pattern CP_S1 and a second sub-pattern CP_S2 may overlap the first vertical scan line SL1_V and may be connected to the first vertical scan line SL1_V through the contact hole CH.

The pixel circuits PXC1, PXC2, and PXC3 of the pixel PXL may be positioned in an area (or a pixel area) partitioned by at least a portion of the first vertical power line PL1_V, the first horizontal power line PL1_H, the second vertical power line PL2_V, and the second horizontal power line PL2_H. The first pixel circuit PXC1 may be positioned adjacent to the third pixel circuit PXC3 in the first direction (X-axis direction), and the second pixel circuit PXC2 may be positioned adjacent to the third pixel circuit PXC3 in a direction opposite to the first direction (X-axis direction).

In the third pixel circuit PXC3, a first semiconductor pattern SCP1 may extend in the first direction (X-axis direction) from the first vertical power line PL1_V. The first semiconductor pattern SCP1 may configure the first transistor T1. One end of the first semiconductor pattern SCP1 may be connected to the first vertical power line PL1_V through the contact hole CH. Another end of the first semiconductor pattern SCP1 may overlap capacitor electrodes CE1, CE2, and CE3, and may be connected to the first capacitor electrode CE1 and the third capacitor electrode CE3 through the contact hole CH.

The first capacitor electrode CE1 and the third capacitor electrode CE3 may have an “L” shape of planar shape, and may have areas substantially identical to or similar to each other except for a protrusion. The second capacitor electrode CE2 (or the gate electrode of the first transistor T1) may be covered by the first capacitor electrode CE1 in a plan view except for the protrusions. For example, the second capacitor electrode CE2 may be entirely positioned inside from an edge of the first capacitor electrode CE1 (or the third capacitor electrode CE3) by a specific distance (for example, about 1 μm to about 2 μm). The second capacitor electrode CE2 may overlap the first and third capacitor electrodes CE1 and CE3 in most areas except for an area where the contact hole CH is formed. For example, the second capacitor electrode CE2 may have a “W” shape of planar shape. However, the present disclosure is not limited thereto, and a shape of the second capacitor electrode CE2 may vary according to a position of the contact hole CH adjacent to the second capacitor electrode CE2.

The first capacitor electrode CE1 may be formed of the first conductive layer, the second capacitor electrode CE2 may be formed of a second conductive layer, and the third capacitor electrode CE3 may be formed of the third conductive layer. The first capacitor electrode CE1 and the second capacitor electrode CE2 may overlap to configure a first sub-capacitor, and the second capacitor electrode CE2 and the third capacitor electrode CE3 may overlap to configure a second sub-capacitor. The third capacitor electrode CE3 may be connected to the first capacitor electrode CE1 through the contact hole CH, and thus the first sub-capacitor and the second sub-capacitor may be connected in parallel to configure the storage capacitor Cst. When the storage capacitor Cst includes the first and second sub-capacitors formed by the capacitor electrodes CE1, CE2, and CE3, a capacitance of the storage capacitor Cst may be sufficiently secured compared to a storage capacitor including only the first sub-capacitor or the second sub-capacitor. Therefore, an influence of a parasitic capacitor may be alleviated or eliminated.

One end of the second capacitor electrode CE2 may overlap a channel area of the first semiconductor pattern SCP1, and the second capacitor electrode CE2 may configure the gate electrode of the first transistor T1. In a plan view, another end of the second capacitor electrode CE2 may extend in the second direction (Y-axis direction) than the first and third capacitor electrodes CE1 and CE3. Another end of the second capacitor electrode CE2 may be connected to a first bridge pattern BRP1 through the contact hole CH.

A portion of the third capacitor electrode CE3 of the third pixel circuit PXC3 may extend toward the second data line DL2 and may be connected to a third bridge electrode BRE3 overlapping the second data line DL2. The third bridge electrode BRE3 may be connected to the first pixel electrode CNE1 (refer to FIG. 4) of the third pixel PXL3 through a second contact hole CNT2. A portion of the third capacitor electrode CE3 of the first pixel circuit PXC1 may extend toward the first vertical power line PL1_V and may be connected to a first bridge electrode BRE1. The first bridge electrode BRE1 may be connected to the first pixel electrode CNE1 (refer to FIG. 4) of the first pixel PXL1 through the second contact hole CNT2. Similarly, a portion of the third capacitor electrode CE3 of the second pixel circuit PXC2 may extend toward the first vertical power line PL1_V and may be connected to a second bridge electrode BRE2. The second bridge electrode BRE2 may be connected to the first pixel electrode CNE1 (refer to FIG. 4) of the second pixel PXL2 through the second contact hole CNT2. In one or more embodiments, a fourth bridge electrode BRE4 may be connected to the second vertical power line PL2_V or the second horizontal power line PL2_H, and may be connected to the second pixel electrode CNE2 (refer to FIG. 4) through a third contact hole CNT3. The bridge electrodes BRE1, BRE2, BRE3, and BRE4 may be formed of the second conductive layer together with the second capacitor electrode CE2. A first contact hole CNT1 is disposed adjacent to the second contact hole CNT2.

In the third pixel circuit PXC3, a second semiconductor pattern SCP2 may be positioned to be spaced from the first semiconductor pattern SCP1 in an oblique direction (for example, a direction between the first direction (X-axis direction) and the second direction (Y-axis direction)) and may extend in the first direction (X-axis direction). The second semiconductor pattern SCP2 may configure the second transistor T2. One end of the second semiconductor pattern SCP2 may be connected to the first bridge pattern BRP1 through the contact hole CH. Another end of the second semiconductor pattern SCP2 may overlap the third data line DL3 and may be connected to the third data line DL3 through a bridge pattern (for example, a second bridge pattern BPR2).

In the third pixel circuit PXC3, a third semiconductor pattern SCP3 may be positioned to be spaced from the second semiconductor pattern SCP2 in a direction opposite to the second direction (Y-axis direction) and may extend in the first direction (X-axis direction). The third semiconductor pattern SCP3 may configure the third transistor T3. One end of the third semiconductor pattern SCP3 may be connected to the first and third capacitor electrodes CE1 and CE3 through the contact hole CH. Another end of the third semiconductor pattern SCP3 may overlap the sensing line SEN and may be connected to the sensing line SEN through the bridge pattern (for example, the third bridge pattern BPR3). The bridge patterns BRP1, BRP2, and BPR3 may be formed of the third conductive layer together with the third capacitor electrode CE3.

One end of a first scan connection line SL1_C may be connected to the first horizontal scan line SL1_H, extend from the first horizontal scan line SL1_H in the second direction (Y-axis direction), overlap the second and third semiconductor patterns SCP2 and SCP3 of the pixel circuits PXC1, PXC2, and PXC3, and configure the gate electrodes of each of the second and third transistors T2 and T3.

As described above, the storage capacitor Cst may include the first and second sub-capacitors configured of the first, second, and third capacitor electrodes CE1, CE2, and CE3 overlapping each other, and the capacitance of the storage capacitor Cst may be sufficiently secured compared to the storage capacitor including only the first sub-capacitor or the second sub-capacitor.

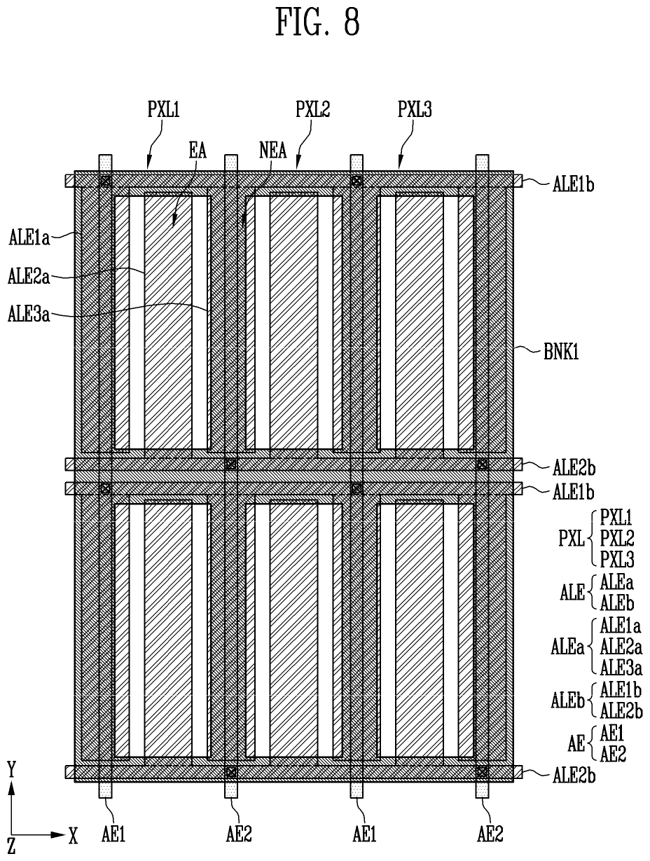

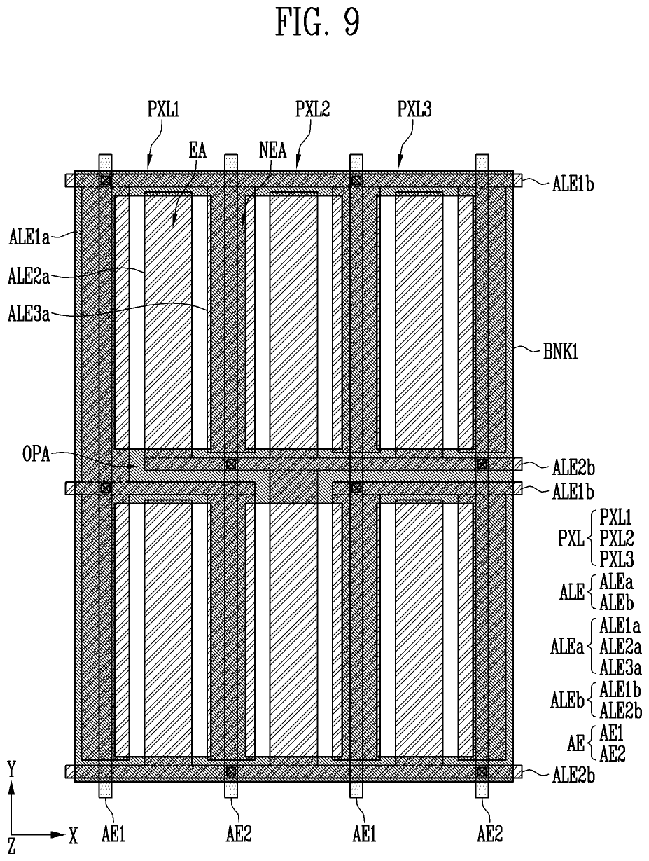

FIGS. 8 and 9 are plan views illustrating first to third pixels according to one or more embodiments.

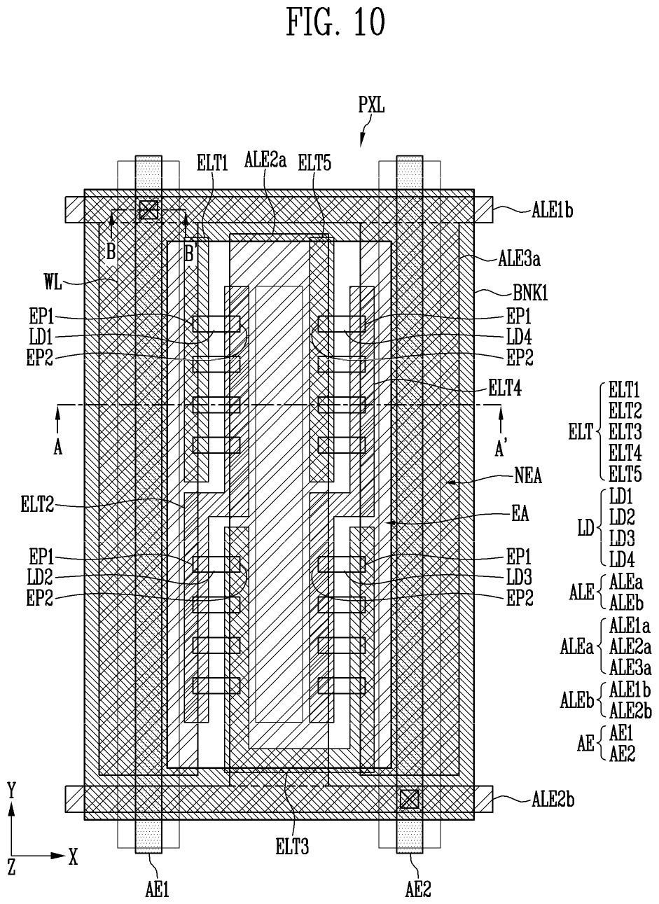

Referring to FIGS. 8 and 9, each of the pixels PXL may include an emission area EA and a non-emission area NEA. The emission area EA may be an area where the light emitting elements LD (refer to FIG. 10) may be included and thus light may be emitted. The non-emission area NEA may be disposed to surround the emission area EA. The non-emission area NEA may be an area in which a first bank BNK1 surrounding the emission area EA is provided. The first bank BNK1 may be provided in the non-emission area NEA and may be disposed to at least partially surround the emission area EA.

The first bank BNK1 may include an opening overlapping the emission area EA. The opening of the first bank BNK1 may provide a space in which the light emitting elements LD, to be described later, may be provided. For example, a desired type and/or amount of light emitting elements LD may be supplied to the space partitioned by the opening of the first bank BNK1.

Alignment electrodes ALE may be provided in the emission area EA and/or the non-emission area NEA. The alignment electrodes ALE may include a first area ALEa and a second area ALEb. The first area ALEa of the alignment electrodes ALE may extend along the second direction (Y-axis direction) in the emission area EA and may be spaced from each other along the first direction (X-axis direction). The first area ALEa of the alignment electrodes ALE may include a first alignment electrode ALE1a, a second alignment electrode ALE2a, and a third alignment electrode ALE3a sequentially arranged along the first direction (X-axis direction). A pair of first to third alignment electrodes ALE1a, ALE2a, and ALE3a adjacent to each other may receive different signals during an alignment step of the light emitting elements LD. For example, when the first to third alignment electrodes ALE1a, ALE2a, and ALE3a are sequentially arranged along the first direction (X-axis direction), the first alignment electrode ALE1a may receive a first alignment signal, the second alignment electrode ALE2a may receive a second alignment signal, and the third alignment electrode ALE3a may receive the first alignment signal.

The second area ALEb of the alignment electrodes ALE may extend along the first direction (X-axis direction) in the non-emission area NEA and may be spaced from each other along the second direction (Y-axis direction). The second area ALEb of the alignment electrodes ALE may include a first alignment line ALE1b and a second alignment line ALE2b spaced along the second direction (Y-axis direction). The first alignment line ALE1b and the second alignment line ALE2b may be alternately disposed along the second direction (Y-axis direction).

The second area ALEb of the alignment electrodes ALE may electrically connect at least some of the first to third alignment electrodes ALE1a, ALE2a, and ALE3a spaced from each other. For example, referring to FIG. 8, the first alignment line ALE1b may electrically connect the first alignment electrode ALE1a and the third alignment electrode ALE3a of pixels PXL adjacent in the first direction (X-axis direction). The second alignment line ALE2b may electrically connect the second alignment electrodes ALE2a of the pixels PXL adjacent in the first direction (X-axis direction). Alternatively, referring to FIG. 9, the second area ALEb of the alignment electrodes ALE may include an open portion OPA that is at least partially removed, and may be electrically connected to the first area ALEa of the alignment electrodes ALE of pixels PXL adjacent in the second direction (Y-axis direction) through the open portion OPA. For example, the first alignment electrode ALE1a may be electrically connected to the first alignment line ALE1b of the pixel PXL adjacent in the second direction (Y-axis direction) through the open portion OPA of the second alignment line ALE2b. The second alignment electrode ALE2a may be electrically connected to the second alignment line ALE2b of the pixel PXL adjacent in the second direction (Y-axis direction) through the open portion OPA of the first alignment line ALE1b.

Auxiliary electrodes AE may be provided in the non-emission area NEA. The auxiliary electrodes AE may overlap the first bank BNK1. The auxiliary electrodes AE may overlap the first area ALEa of the alignment electrode ALE described above. For example, the auxiliary electrodes AE may overlap the first alignment electrode ALE1a and/or the third alignment electrode ALE3a described above. The auxiliary electrodes AE may cross the second area ALEb of the alignment electrode ALE described above.

The auxiliary electrodes AE may extend along the second direction (Y-axis direction) in the non-emission area NEA and may be spaced from each other along the first direction (X-axis direction). The auxiliary electrodes AE may be commonly disposed in the pixels PXL adjacent in the second direction (Y-axis direction). The auxiliary electrodes AE may include a first auxiliary electrode AE1 and a second auxiliary electrode AE2 spaced from each other along the first direction (X-axis direction). The first auxiliary electrode AE1 and the second auxiliary electrode AE2 may be alternately disposed along the first direction (X-axis direction).

The first auxiliary electrode AE1 and the second auxiliary electrode AE2 may receive different signals during the alignment step of the light emitting elements LD. For example, the first auxiliary electrode AE1 may receive the first alignment signal described above, and the second auxiliary electrode AE2 may receive the second alignment signal described above. For example, the first auxiliary electrode AE1 may be electrically connected to the first alignment line ALE1b through a contact hole at a point where the first auxiliary electrode AE1 crosses the first alignment line ALE1b. The second auxiliary electrode AE2 may be electrically connected to the second alignment line ALE2b through a contact hole at a point where the second auxiliary electrode AE2 crosses the second alignment line ALE2b.

The alignment electrodes ALE and the auxiliary electrodes AE may be insulated from the signal lines of the pixel circuit PXC described with reference to FIG. 7. Accordingly, because an influence of an electric field may be reduced or minimized when aligning the light emitting elements LD by preventing an alignment signal from being applied to the signal lines of the pixel circuit PXC, for example, the first vertical power line PL1_V, the first horizontal power line PL1_H, the second vertical power line PL2_V, and/or the second horizontal power line PL2_H, the alignment degree may be improved. In addition, because a voltage drop of the alignment electrodes ALE may be reduced or minimized by forming the first area ALEa and the second area ALEb of the alignment electrodes ALE in a mesh structure and additionally using the auxiliary electrodes AE, the alignment degree of the light emitting elements LD may be improved.

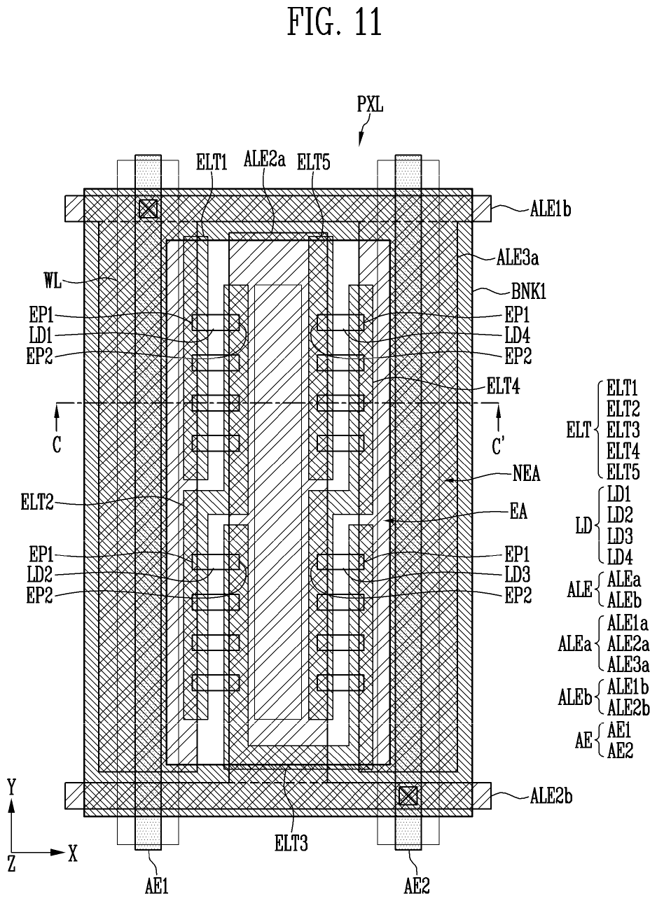

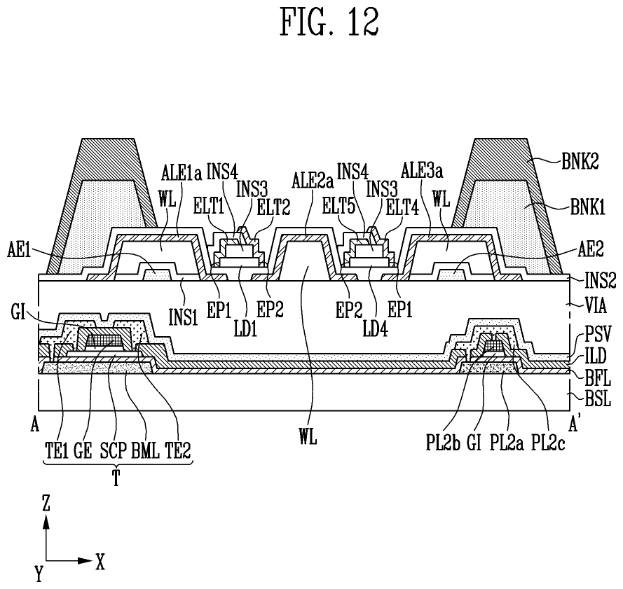

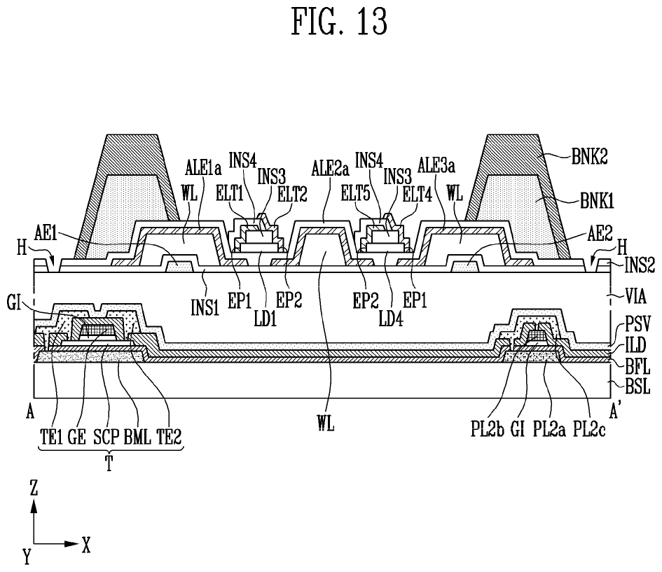

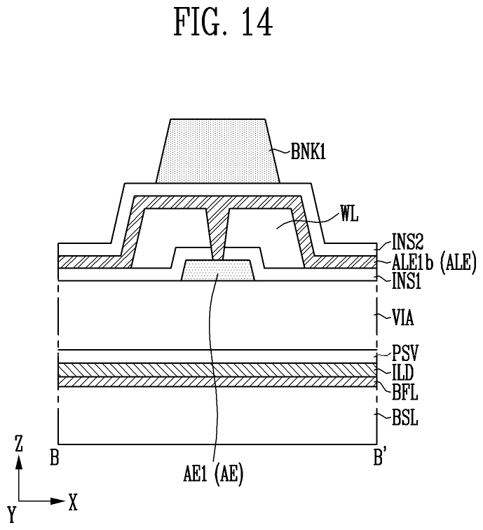

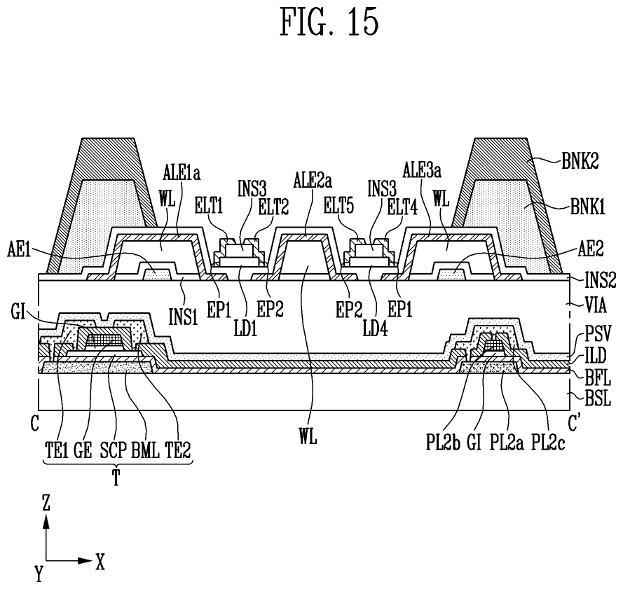

FIGS. 10 and 11 are plan views illustrating a pixel according to one or more embodiments. FIGS. 12 and 13 are cross-sectional views taken along the line A-A′ of FIG. 10. FIG. 14 is a cross-sectional view taken along the line B-B′ of FIG. 10. FIG. 15 is a cross-sectional view taken along the line C-C′ of FIG. 11. For example, FIGS. 10 and 11 may be any one of the first to third pixels PXL1, PXL2, and PXL3 configuring the pixel unit PXU of FIG. 3, and the first to third pixels PXL1, PXL2, PXL3 may have structures identical to or similar to each other. FIGS. 10 and 11 disclose an embodiment in which each pixel PXL includes the light emitting elements LD disposed in four series stages as shown in FIG. 6, but the number of series stages of each pixel PXL may be variously changed according to one or more embodiments.

Each pixel PXL may include bank patterns WL, the alignment electrodes ALE, the light emitting elements LD, and/or connection electrodes ELT.

The bank patterns WL may be provided at least in the emission area EA. The bank patterns WL may be at least partially disposed in the non-emission area NEA. The bank patterns WL may extend along the second direction (Y-axis direction) and may be spaced from each other along the first direction (X-axis direction).

Each of the bank patterns WL may overlap at least a portion of the first to third alignment electrodes ALE1a, ALE2a, and ALE3a at least in the emission area EA. For example, each of the bank patterns WL may be provided under the first to third alignment electrodes ALE1a, ALE2a, and ALE3a. As the bank patterns WL are provided under one area of each of the first to third alignment electrodes ALE1a, ALE2a, and ALE3a, one area of each of the first to third alignment electrodes ALE1a, ALE2a, and ALE3a may protrude in an upper direction, that is, a third direction (Z-axis direction) in an area where the bank patterns WL are formed. When the bank patterns WL and/or the first to third alignment electrodes ALE1a, ALE2a, and ALE3a include a reflective material, a reflective wall structure may be formed around the light emitting elements LD. Accordingly, because light emitted from the light emitting elements LD may be emitted in an upper direction (for example, a front direction of the display panel PNL including a viewing angle range) of the pixel PXL, light emission efficiency of the display panel PNL may be improved.

Each of the light emitting elements LD may be provided between the bank patterns WL in the emission area EA. Each of the light emitting elements LD may be aligned between the first to third alignment electrodes ALE1a, ALE2a, and ALE3a in the emission area EA. Each of the light emitting elements LD may be electrically connected between a pair of connection electrodes ELT.

The first light emitting element LD1 may be aligned between the first and second alignment electrodes ALE1a and ALE2a. The first light emitting element LD1 may be electrically connected between first and second connection electrodes ELT1 and ELT2. For example, the first light emitting element LD1 may be aligned in a first area (for example, an upper area) of the first and second alignment electrodes ALE1a and ALE2a, the first end EP1 of the first light emitting element LD1 may be electrically connected to the first connection electrode ELT1, and the second end EP2 of the first light emitting element LD1 may be electrically connected to the second connection electrode ELT2.

The second light emitting element LD2 may be aligned between the first and second alignment electrodes ALE1a and ALE2a. The second light emitting element LD2 may be electrically connected between second and third connection electrodes ELT2 and ELT3. For example, the second light emitting element LD2 may be aligned in a second area (for example, a lower area) of the first and second alignment electrodes ALE1a and ALE2a, the first end EP1 of the second light emitting element LD2 may be electrically connected to the second connection electrode ELT2, and the second end EP2 of the second light emitting element LD2 may be electrically connected to the third connection electrode ELT3.

The third light emitting element LD3 may be aligned between the second and third alignment electrodes ALE2a and ALE3a. The third light emitting element LD3 may be electrically connected between third and fourth connection electrodes ELT3 and ELT4. For example, the third light emitting element LD3 may be aligned in a second area (for example, a lower area) of the second and third alignment electrodes ALE2a and ALE3a, the first end EP1 of the third light emitting element LD3 may be electrically connected to the third connection electrode ELT3, and the second end EP2 of the third light emitting element LD3 may be electrically connected to the fourth connection electrode ELT4.

The fourth light emitting element LD4 may be aligned between the second and third alignment electrodes ALE2a and ALE3a. The fourth light emitting element LD4 may be electrically connected between fourth and fifth connection electrodes ELT4 and ELTS. For example, the fourth light emitting element LD4 may be aligned in a first area (for example, an upper area) of the second and third alignment electrodes ALE2a and ALE3a, the first end EP1 of the fourth light emitting element LD4 may be electrically connected to the fourth connection electrode ELT4, and the second end EP2 of the fourth light emitting element LD4 may be electrically connected to the fifth connection electrode ELTS.

For example, the first light emitting element LD1 may be positioned in an upper left area of the emission area EA, and the second light emitting element LD2 may be positioned in a lower left area of the emission area EA. The third light emitting element LD3 may be positioned in a lower right area of the emission area EA, and the fourth light emitting element LD4 may be positioned in an upper right area of the emission area EA. However, an arrangement, a connection structure, and/or the like of the light emitting elements LD may be variously changed according to a structure of the light emitting unit EMU, the number of series stages, and the like.

Each of the connection electrodes ELT may be provided at least in the emission area EA and may be disposed to overlap at least one electrode ALE and/or the light emitting element LD. For example, each of the connection electrodes ELT may be formed on the alignment electrodes ALE and/or the light emitting elements LD to overlap the first to third alignment electrodes ALE1a, ALE2a, and ALE3a and/or the light emitting elements LD, and may be electrically connected to the light emitting elements LD.

The first connection electrode ELT1 may be disposed in an upper area of the first alignment electrode ALE1a and on the first ends EP1 of the first light emitting elements LD1, and may be electrically connected to the first ends EP1 of the first light emitting elements LD1.

The second connection electrode ELT2 may be disposed in an upper area of the second alignment electrode ALE2a and on the second ends EP2 of the first light emitting elements LD1, and may be electrically connected to the second ends EP2 of the first light emitting elements LD1. The second connection electrode ELT2 may be disposed in a lower area of a first electrode ALE1a and on the first ends EP1 of the second light emitting elements LD2, and may be electrically connected to the first ends EP1 of the second light emitting elements LD2. For example, the second connection electrode ELT2 may electrically connect the second ends EP2 of the first light emitting elements LD1 and the first ends EP1 of the second light emitting elements LD2. To this end, the second connection electrode ELT2 may have a curved shape. For example, the second connection electrode ELT2 may have a bent or curved structure at a boundary between an area where the at least one first light emitting element LD1 is arranged and an area where the at least one second light emitting element LD2 is arranged.

The third connection electrode ELT3 may be disposed in a lower area of the second alignment electrode ALE2a and on the second ends EP2 of the second light emitting elements LD2, and may be electrically connected to the second ends EP2 of the second light emitting elements LD2. The third connection electrode ELT3 may be disposed in a lower area of the third alignment electrode ALE3a and on the first ends EP1 of the third light emitting elements LD3, and may be electrically connected to the first ends EP1 of the third light emitting elements LD3. For example, the third connection electrode ELT3 may electrically connect the second ends EP2 of the second light emitting elements LD2 and the first ends EP1 of the third light emitting elements LD3 in the emission area EA. To this end, the third connection electrode ELT3 may have a curved shape. For example, the third connection electrode ELT3 may have a bent or curved structure at a boundary between an area where at least one second light emitting element LD2 is arranged and an area where at least one third light emitting element LD3 is arranged.

The fourth connection electrode ELT4 may be disposed in a lower area of the second alignment electrode ALE2a and on the second ends EP2 of the third light emitting elements LD3, and may be electrically connected to the second ends EP2 of the third light emitting elements LD3. The fourth connection electrode ELT4 may be disposed in an upper area of the third alignment electrode ALE3a and on the first ends EP1 of the fourth light emitting elements LD4, and may be electrically connected to the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4 in the emission area EA. To this end, the fourth connection electrode ELT4 may have a curved shape. For example, the fourth connection electrode ELT4 may have a bent or curved structure at a boundary between an area where at least one third light emitting element LD3 is arranged and an area where at least one fourth light emitting element LD4 is arranged.

The fifth connection electrode ELTS may be disposed in an upper area of the second alignment electrode ALE2a and on the second ends EP2 of the fourth light emitting elements LD4, and may be electrically connected to the second ends EP2 of the fourth light emitting elements LD4.

As shown in FIG. 10, the first connection electrode ELT1, the third connection electrode ELT3, and/or the fifth connection electrode ELTS may be formed of the same conductive layer as each other. The second connection electrode ELT2 and the fourth connection electrode ELT4 may be formed of the same conductive layer as each other. For example, the first connection electrode ELT1, the third connection electrode ELT3, and/or the fifth connection electrode ELT5 may be formed of the first conductive layer, and the second connection electrode ELT2 and the fourth connection electrode ELT4 may be formed as the second conductive layer.

As shown in FIG. 11, the first to fifth connection electrodes ELT1, ELT2, ELT3, ELT4, and ELT5 may be formed of the same conductive layer as each other. As described above, when the first to fifth connection electrodes ELT1, ELT2, ELT3, ELT4, and ELT5 are formed of the same conductive layer, the number of masks may be reduced and a manufacturing process may be simplified.

In a method described above, the light emitting elements LD aligned between the first to third alignment electrodes ALE1a, ALE2a, and ALE3a may be connected in a desired form using the connection electrodes ELT. For example, the first light emitting elements LD1, the second light emitting elements LD2, the third light emitting elements LD3, and the fourth light emitting elements LD4 may be sequentially connected in series using the connection electrodes ELT.

Hereinafter, a cross-sectional structure of the pixel PXL is described in detail with reference to FIGS. 12 to 15. The pixels PXL according to one or more embodiments may include circuit element including transistors T disposed on the base layer BSL, and various signal lines connected to the circuit elements. The first and second auxiliary electrodes AE1 and AE2, the first to third alignment electrodes ALE1a, ALE2a, and ALE3a, the light emitting elements LD, the connection electrodes ELT, the first bank BNK1, and/or a second bank BNK2 may be disposed on the circuit elements.

The base layer BSL may configure a base member, and may be a rigid or flexible substrate or film. For example, the base layer BSL may be a rigid substrate formed of glass or tempered glass, a flexible substrate (or thin film) of a plastic or metal material, or an insulating layer of at least one layer. A material and/or a physical property of the base layer BSL are/is not particularly limited. In one or more embodiments, the base layer BSL may be substantially transparent. Here, “substantially transparent” may mean that light may be transmitted at a desired transmittance or more. In another embodiment, the base layer BSL may be translucent or opaque. The base layer BSL may include a reflective material according to one or more embodiments.

The lower conductive layer BML and a first power conductive layer PL2a may be disposed on the base layer BSL. The lower conductive layer BML and the first power conductive layer PL2a may be disposed on the same layer. For example, the lower conductive layer BML and the first power conductive layer PL2a may be concurrently (e.g., simultaneously) formed in the same process, but are not limited thereto. The first power conductive layer PL2a may configure the second power line PL2 described with reference to FIG. 4 or the like.

Each of the lower conductive layer BML and the first power conductive layer PL2a may be formed as a single layer or multiple layers formed of one or more selected from among molybdenum (Mo), copper (Cu), aluminum (Al), chromium (Cr), gold (Au), titanium (Ti), nickel (Ni), neodymium (Nd), indium (In), tin (Sn), and an oxide and/or an alloy thereof.

A buffer layer BFL may be disposed on the lower conductive layer BML and the first power conductive layer PL2a. The buffer layer BFL may prevent an impurity from being diffused into the circuit element. The buffer layer BFL may be configured as a single layer, but may be configured as multiple layers of at least two or more layers. When the buffer layer BFL is formed of multiple layers, each layer may be formed of the same material or may be formed of different materials.

A semiconductor pattern SCP may be disposed on the buffer layer BFL. For example, each semiconductor pattern SCP may include a first area that is in contact with a first transistor electrode TE1, a second area that is in contact with a second transistor electrode TE2, and a channel area positioned between the first and second areas. According to one or more embodiments, one of the first and second areas may be a source area and the other may be a drain area.

According to one or more embodiments, the semiconductor pattern SCP may be formed of one or more selected from among polysilicon, amorphous silicon, oxide semiconductor, and/or the like. The channel area of the semiconductor pattern SCP may be an intrinsic semiconductor as a semiconductor pattern that is not doped with an impurity, and each of the first and second areas of the semiconductor pattern SCP may be a semiconductor doped with an impurity.

A gate insulating layer GI may be disposed on the buffer layer BFL and the semiconductor pattern SCP. For example, the gate insulating layer GI may be disposed between the semiconductor pattern SCP and a gate electrode GE. The gate insulating layer GI may be disposed between the buffer layer BFL and a second power conductive layer PL2b. The gate insulating layer GI may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The gate electrode GE of the transistor T and the second power conductive layer PL2b may be disposed on the gate insulating layer GI. The gate electrode GE and the second power conductive layer PL2b may be disposed on (or at) the same layer. For example, the gate electrode GE and the second power conductive layer PL2b may be concurrently (e.g., simultaneously) formed in the same process, but are not limited thereto. The gate electrode GE may be disposed to overlap the semiconductor pattern SCP in the third direction (Z-axis direction, e.g., a thickness direction of the base layer BSL) on the gate insulating layer GI. The second power conductive layer PL2b may be disposed to overlap the first power conductive layer PL2a in the third direction (Z-axis direction) on the gate insulating layer GI. The second power conductive layer PL2b may configure the second power line PL2 described with reference to FIG. 4 or the like together with the first power conductive layer PL2a.

Each of the gate electrode GE and the second power conductive layer PL2b may be formed as a single layer or multiple layers formed of one or more selected from among molybdenum (Mo), copper (Cu), aluminum (Al), chromium (Cr), gold (Au), titanium (Ti), nickel (Ni), neodymium (Nd), indium (In), tin (Sn), and an oxide and/or an alloy thereof. For example, each of the gate electrode GE and the second power conductive layer PL2b may be formed as multiple layers in which titanium (Ti), copper (Cu), and/or indium tin oxide (ITO) are sequentially or repeatedly stacked.

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. The interlayer insulating layer ILD may be disposed between the second power conductive layer PL2b and a third power conductive layer PL2c.

The interlayer insulating layer ILD may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The first and second transistor electrodes TE1 and TE2 of the transistor T and the third power conductive layer PL2c may be disposed on the interlayer insulating layer ILD. The first and second transistor electrodes TE1 and TE2 and the third power conductive layer PL2c may be disposed on (or at) the same layer. For example, the first and second transistor electrodes TE1 and TE2 and the third power conductive layer PL2c may be concurrently (e.g., simultaneously) formed in the same process, but are not limited thereto.

The first and second transistor electrodes TE1 and TE2 may be disposed to overlap the semiconductor pattern SCP in the third direction (Z-axis direction). The first and second transistor electrodes TE1 and TE2 may be electrically connected to the semiconductor pattern SCP. For example, the first transistor electrode TE1 may be electrically connected to the first area of the semiconductor pattern SCP through a contact hole passing through the interlayer insulating layer ILD. The first transistor electrode TE1 may be electrically connected to the lower conductive layer BML through a contact hole passing through the interlayer insulating layer ILD and the buffer layer BFL. The second transistor electrode TE2 may be electrically connected to the second area of the semiconductor pattern SCP through a contact hole passing through the interlayer insulating layer ILD. According to one or more embodiments, one of the first and second transistor electrodes TE1 and TE2 may be a source electrode, and the other may be a drain electrode.

The third power conductive layer PL2c may be disposed to overlap the first power conductive layer PL2a and/or the second power conductive layer PL2b in the third direction (Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole passing through the interlayer insulating layer ILD and the buffer layer BFL. The third power conductive layer PL2c may be electrically connected to the second power conductive layer PL2b through a contact hole passing through the interlayer insulating layer ILD. The third power conductive layer PL2c may configure the second power line PL2 described with reference to FIG. 5 or the like together with the first power conductive layer PL2a and/or the second power conductive layer PL2b.

The first and second transistor electrodes TE1 and TE2 and the third power conductive layer PL2c may be formed as a single layer or multiple layers formed of one or more selected from among molybdenum (Mo), copper (Cu), aluminum (Al), chromium (Cr), gold (Au), titanium (Ti), nickel (Ni), neodymium (Nd), indium (In), tin (Sn), and/or an oxide and/or an alloy thereof.

A protective layer PSV may be disposed on the first and second transistor electrodes TE1 and TE2 and the third power conductive layer PL2c. The protective layer PSV may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

A via layer VIA may be disposed on the protective layer PSV. The via layer VIA may be formed of an organic material to planarize a lower step difference due to the transistor T or the signal lines of the pixel circuit PXC (refer to FIG. 7). For example, the via layer VIA may include an organic material such as an acrylates resin, an epoxy resin, a phenolic resin, a polyamides resin, a polyimides resin, a polyesters resin, a polyphenylenesulfides resin, and/or benzocyclobutene (BCB). However, the present disclosure is not necessarily limited thereto, and the via layer VIA may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The first and second auxiliary electrodes AE1 and AE2 may be disposed on the via layer VIA. The first and second auxiliary electrodes AE1 and AE2 may be formed as a single layer or multiple layers formed of one or more selected from among molybdenum (Mo), copper (Cu), aluminum (Al), chromium (Cr), gold (Au), titanium (Ti), nickel (Ni), neodymium (Nd), indium (In), tin (Sn), and/or an oxide and/or an alloy thereof, but are not necessarily limited thereto.

A first insulating layer INS1 may be disposed on the first and second auxiliary electrodes AE1 and AE2. The first insulating layer INS1 may cover the first and second auxiliary electrodes AE1 and AE2. The first insulating layer INS1 may serve to reduce or minimize corrosion of the first and second auxiliary electrodes AE1 and AE2 and may be omitted according to one or more embodiments. The first insulating layer INS1 may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The bank patterns WL may be disposed on the via layer VIA. The bank patterns WL may serve to form a step difference so that the light emitting elements LD may be easily aligned in the emission area EA.

The bank patterns WL may overlap the first and second auxiliary electrodes AE1 and AE2, respectively. As described above, when the bank patterns WL are formed on the first and second auxiliary electrodes AE1 and AE2, even though the first and second auxiliary electrodes AE1 and AE2 are formed thick, a step difference due to this may be flattened. In addition, because an influence of an electric field due to the first and second auxiliary electrodes AE1 and AE2 may be reduced or minimized by covering the first and second auxiliary electrodes AE1 and AE2, the alignment degree of the light emitting elements LD may be improved.

The bank patterns WL may have various shapes according to one or more embodiments. In one or more embodiments, the bank patterns WL may have a shape protruding in the third direction (Z-axis direction) on the base layer BSL. The bank patterns WL may be formed to have an inclined surface inclined at an angle with respect to the base layer BSL. However, the present disclosure is not necessarily limited thereto, and the bank patterns WL may have a side wall of a curved surface, a step shape, or the like. For example, the bank patterns WL may have a cross-section of a semi-circle shape, a semi-ellipse shape, or the like.

The bank patterns WL may include at least one organic material and/or inorganic material. For example, the bank patterns WL may include an organic material such as an acrylates resin, an epoxy resin, a phenolic resin, a polyamides resin, a polyimides resin, a polyesters resin, a polyphenylenesulfides resin, and/or benzocyclobutene (BCB). However, the present disclosure is not necessarily limited thereto, and the bank patterns WL may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

Referring to FIG. 12, the bank patterns WL and the first insulating layer INS1 may have the same shape. For example, the bank patterns WL and the first insulating layer INS1 may be concurrently (e.g., simultaneously) etched in the same process, but are not necessarily limited thereto.

Referring to FIG. 13, the first insulating layer INS1 may be formed on the entire surface of the base layer BSL, and the bank patterns WL may be partially formed on the first insulating layer INS1. As described above, when the first insulating layer INS1 is formed on the entire surface of the base layer BSL, a hole H may be formed in the first insulating layer INS1. The hole H may pass through the first insulating layer INS1 to expose the via layer VIA disposed thereunder. Because an outgas generated in the organic layer may be released to an outside through the hole H, a defect due to the outgas may be reduced or minimized.

The first to third alignment electrodes ALE1a, ALE2a, and ALE3a may be disposed on the via layer VIA and the bank patterns WL. Each of the first to third alignment electrodes ALE1a, ALE2a, and ALE3a may at least partially cover a side surface and/or an upper surface of the bank patterns WL. The first to third alignment electrodes ALE1a, ALE2a, and ALE3a disposed on the bank patterns WL may have a shape corresponding to the bank pattern WL. For example, the first to third alignment electrodes ALE1a, ALE2a, and ALE3a disposed on the bank patterns WL may include an inclined surface or a curved surface having a shape corresponding to a shape of the bank patterns WL. In this case, because the bank patterns WL and the first to third alignment electrodes ALE1a, ALE2a, and ALE3a may reflect the light emitted from the light emitting elements LD and guide the light in a front direction of the pixel PXL, that is, in the third direction (Z-axis direction) as a reflective member, the light emission efficiency of the display panel PNL may be improved.

The first to third alignment electrodes ALE1a, ALE2a, and ALE3a may be disposed to be spaced from each other. The first to third alignment electrodes ALE1a, ALE2a, and ALE3a may be disposed on (or at) the same layer. For example, the first to third alignment electrodes ALE1a, ALE2a, and ALE3a may be concurrently (e.g., simultaneously) formed in the same process, but are not necessarily limited thereto.

The first to third alignment electrodes ALE1a, ALE2a, and ALE3a may receive the alignment signal in the alignment step of the light emitting elements LD. Accordingly, an electric field may be formed between the first to third alignment electrodes ALE1a, ALE2a, and ALE3a, and thus the light emitting elements LD provided to each of the pixels PXL may be aligned between the first to third alignment electrodes ALE1a, ALE2a, and ALE3a.

Referring to FIG. 14, the second area ALEb of the alignment electrodes ALE, for example, the first alignment line ALE1b may be electrically connected to the auxiliary electrodes AE disposed thereunder, for example, the first auxiliary electrode AE1 through a contact hole passing through the bank patterns WL and the first insulating layer INS1.

A second insulating layer INS2 may be disposed on the first to third alignment electrodes ALE1a, ALE2a, and ALE3a. The second insulating layer INS2 may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

According to one or more embodiments, as shown in FIG. 13, a hole H may be formed in the second insulating layer INS2. The hole H may pass through the second insulating layer INS2 and the first insulating layer INS1 to expose the via layer VIA disposed thereunder. Because the outgas generated in the organic layer may be released to the outside through the hole H, the defect due to the outgas may be reduced or minimized. The first bank BNK1 may be disposed on the second insulating layer INS2.

The first bank BNK1 may include an opening overlapping the emission area EA. The opening of the first bank BNK1 may provide a space in which the light emitting elements LD may be provided in the step of supplying the light emitting elements LD to each of the pixels PXL. For example, a desired type and/or amount of light emitting element ink may be supplied to the space partitioned by the opening of the first bank BNK1.

The first bank BNK1 may include an organic material such as an acrylates resin, an epoxy resin, a phenolic resin, a polyamides resin, a polyimides resin, a polyesters resin, a polyphenylenesulfides resin, and/or benzocyclobutene (BCB). However, the present disclosure is not necessarily limited thereto, and the first bank BNK1 may include various types of inorganic materials including silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The light emitting elements LD may be disposed between the first to third alignment electrodes ALE1a, ALE2a, and ALE3a. The light emitting elements LD may be provided in the opening of the first bank BNK1 and disposed between the bank patterns WL on the first insulating layer INS1.

The light emitting elements LD may be prepared in a form dispersed in a light emitting element ink and supplied to each of the pixels PXL through an inkjet printing method or the like. For example, the light emitting elements LD may be dispersed in a volatile solvent and provided to each of the pixels PXL. Subsequently, when an alignment signal is supplied to the first to third alignment electrodes ALE1a, ALE2a, and ALE3a, an electric field may be formed between the first to third alignment electrodes ALE1a, ALE2a, and ALE3a, and thus the light emitting elements LD may be aligned. After the light emitting elements LD are aligned, the light emitting elements LD may be stably arranged between the first to third alignment electrodes ALE1a, ALE2a, and ALE3a by evaporating the solvent or removing the solvent in another method.

A third insulating layer INS3 may be disposed on the light emitting elements LD. For example, the third insulating layer INS3 may be partially provided on the light emitting elements LD and may expose the first and second ends EP1 and EP2 of the light emitting elements LD. When the third insulating layer INS3 is formed on the light emitting elements LD after alignment of the light emitting elements LD is completed, the light emitting elements LD may be prevented from being separated from an aligned position.

The third insulating layer INS3 may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The connection electrodes ELT may be disposed on the first and second ends EP1 and EP2 of the light emitting elements LD exposed by the third insulating layer INS3. The first connection electrode ELT1 may be directly disposed on the first end EP1 of the first light emitting elements LD1 to contact the first end EP1 of the first light emitting elements LD1.

The second connection electrode ELT2 may be directly disposed on the second end EP2 of the first light emitting elements LD1 to contact the second end EP2 of the first light emitting elements LD1. In addition, the second connection electrode ELT2 may be directly disposed on the first end EP1 of the second light emitting elements LD2 to contact the first end EP1 of the second light emitting elements LD2. That is, the second connection electrode ELT2 may electrically connect the second end EP2 of the first light emitting elements LD1 and the first end EP1 of the second light emitting elements LD2.

Similarly, the third connection electrode ELT3 may be directly disposed on the second end EP2 of the second light emitting elements LD2 to contact the second end EP2 of the second light emitting elements LD2. The third connection electrode ELT3 may be directly disposed on the first end EP1 of the third light emitting elements LD3 to contact the first end EP1 of the third light emitting elements LD3. That is, the third connection electrode ELT3 may electrically connect the second end EP2 of the second light emitting elements LD2 and the first end EP1 of the third light emitting elements LD3.

Similarly, the fourth connection electrode ELT4 may be directly disposed on the second end EP2 of the third light emitting elements LD3 to contact the second end EP2 of the third light emitting elements LD3. The fourth connection electrode ELT4 may be directly disposed on the first end EP1 of the fourth light emitting elements LD4 to contact the first end EP1 of the fourth light emitting elements LD4. That is, the fourth connection electrode ELT4 may electrically connect the second end EP2 of the third light emitting elements LD3 and the first end EP1 of the fourth light emitting elements LD4.

Similarly, the fifth connection electrode ELTS may be directly disposed on the second end EP2 of the fourth light emitting elements LD4 to contact the second end EP2 of the fourth light emitting elements LD4. According to one or more embodiments, the first connection electrode ELT1 and/or the fifth connection electrode ELTS may be electrically connected to the signal lines of the pixel circuit PXC (refer to FIG. 7) described above, but are not necessarily limited thereto.

As shown in FIGS. 10-13, the first connection electrode ELT1, the third connection electrode ELT3, and/or the fifth connection electrode ELTS may be formed of the same conductive layer as each other. The second connection electrode ELT2 and the fourth connection electrode ELT4 may be formed of the same conductive layer as each other. For example, the first connection electrode ELT1, the third connection electrode ELT3, and/or the fifth connection electrode ELTS may be formed of the first conductive layer, and the second connection electrode ELT2 and the fourth connection electrode ELT4 may be formed of the second conductive layer. A fourth insulating layer INS4 may be further disposed between the first conductive layer and the second conductive layer. The fourth insulating layer INS4 may be configured as a single layer or multiple layers, and may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

As shown in FIG. 15, the first to fifth connection electrodes ELT1, ELT2, ELT3, ELT4, and ELT5 may be formed of the same conductive layer as each other. As described above, when the first to fifth connection electrodes ELT1, ELT2, ELT3, ELT4, and ELT5 are formed of the same conductive layer, the number of masks may be reduced and the manufacturing process may be simplified.

In the above-described method, the light emitting elements LD aligned between the first to third alignment electrodes ALE1a, ALE2a, and ALE3a may be connected in a desired form using the connection electrodes ELT. For example, the first light emitting elements LD1, the second light emitting elements LD2, the third light emitting elements LD3, and the fourth light emitting elements LD4 may be connected sequentially in series using the connection electrodes ELT.

The connection electrodes ELT may be formed of various transparent conductive materials. For example, the connection electrodes ELT may include at least one of various transparent conductive materials including one or more selected from among indium tin oxide (ITO), indium zinc oxide (IZO), indium tin zinc oxide (ITZO), aluminum zinc oxide (AZO), gallium zinc oxide (GZO), zinc tin oxide (ZTO), or gallium tin oxide (GTO), and may be implemented to be substantially transparent or translucent to satisfy a light transmittance. Accordingly, light emitted from the first and second ends EP1 and EP2 of the light emitting elements LD may pass through the connection electrodes ELT and may be emitted to the outside of the display panel PNL.

The second bank BNK2 may be disposed on the first bank BNK1. The second bank BNK2 may include an opening overlapping the emission area EA. The opening of the second bank BNK2 may provide a space in which a color conversion layer to be described later may be provided. For example, a desired type and/or amount of color conversion layer may be supplied to the space partitioned by the opening of the second bank BNK2.

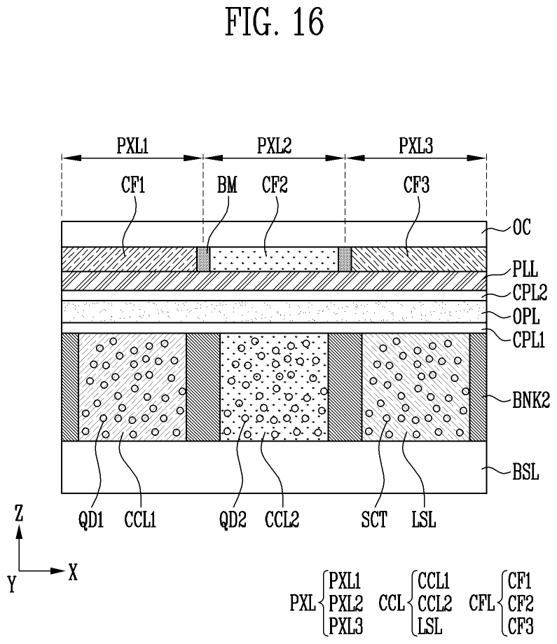

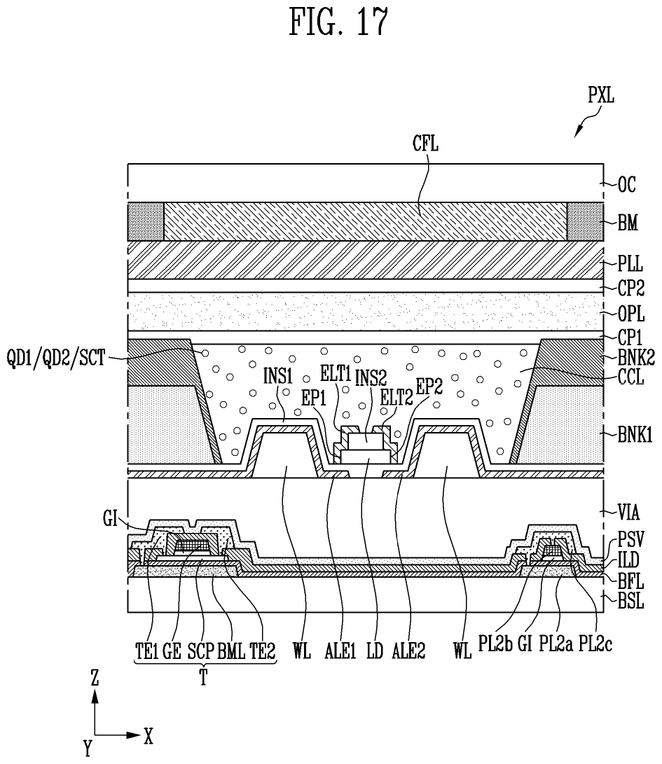

FIG. 16 is a cross-sectional view illustrating first to third pixels according to one or more embodiments. FIG. 17 is a cross-sectional view of a pixel according to one or more embodiments.

FIG. 16 shows a color conversion layer CCL, an optical layer OPL, a color filter layer CFL, a light blocking layer BM, and/or the like. In FIG. 16, a configuration except for the base layer BSL and the second bank BNK2 of FIGS. 12 to 15 is omitted for convenience of description. FIG. 17 illustrates a stack structure of the pixel PXL in detail in relation to the color conversion layer CCL, the optical layer OPL, and/or the color filter layer CFL.

Referring to FIGS. 16 and 17, the second bank BNK2 may be disposed between or at a boundary between the first to third pixels PXL1, PXL2, and PXL3, and may include an opening each overlapping the first to third pixels PXL1, PXL2, and PXL3. The opening of the second bank BNK2 may provide a space in which the color conversion layer CCL may be provided.

The second bank BNK2 may include an organic material such as acrylates resin, epoxy resin, phenolic resin, polyamides resin, polyimides resin, polyesters resin, polyphenylenesulfides resin, polypropylene (PP), polytetrafluoroethylene (PTFE), and/or benzocyclobutene (BCB).

The color conversion layer CCL may be disposed on the light emitting elements LD in the opening of the second bank BNK2. The color conversion layer CCL may include a first color conversion layer CCL1 disposed in the first pixel PXL1, a second color conversion layer CCL2 disposed in the second pixel PXL2, and a scattering layer LSL disposed in the third pixel PXL3.

In one or more embodiments, the first to third pixels PXL1, PXL2, and PXL3 may include light emitting elements LD that emit light of the same color. For example, the first to third pixels PXL1, PXL2, and PXL3 may include light emitting elements LD emitting light of a third color (or blue). The color conversion layer CCL including color conversion particles may be disposed on each of the first to third pixels PXL1, PXL2, and PXL3 to display a full-color image.

The first color conversion layer CCL1 may include first color conversion particles that convert light of the third color emitted from the light emitting element LD into light of the first color. For example, the first color conversion layer CCL1 may include a plurality of first quantum dots QD1 dispersed in a matrix material such as a base resin.

In one or more embodiments, when the light emitting element LD is a blue light emitting element emitting blue light and the first pixel PXL1 is a red pixel, the first color conversion layer CCL1 may include a first quantum dot QD1 that converts the blue light emitted from the blue light emitting element into red light. The first quantum dot QD1 may absorb the blue light and shift a wavelength according to an energy transition to emit the red light. In one or more embodiments, when the first pixel PXL1 is a pixel of a different color, the first color conversion layer CCL1 may include a first quantum dot QD1 corresponding to the color of the first pixel PXL1.

The second color conversion layer CCL2 may include second color conversion particles that convert light of the third color emitted from the light emitting element LD into light of the second color. For example, the second color conversion layer CCL2 may include a plurality of second quantum dots QD2 dispersed in a matrix material such as a base resin.

In one or more embodiments, when the light emitting element LD is the blue light emitting element emitting the blue light and the second pixel PXL2 is a green pixel, the second color conversion layer CCL2 may include a second quantum dot QD2 that converts the blue light emitted from the blue light emitting element into green light. The second quantum dot QD2 may absorb the blue light and shift a wavelength according to an energy transition to emit the green light. In one or more embodiments, when the second pixel PXL2 is a pixel of a different color, the second color conversion layer CCL2 may include a second quantum dot QD2 corresponding to the color of the second pixel PXL2.

In one or more embodiments, an absorption coefficient of the first quantum dot QD1 and the second quantum dot QD2 may be increased by allowing the blue light having a relatively short wavelength in a visible light area to be incident on each of the first quantum dot QD1 and the second quantum dot QD2. Accordingly, finally, efficiency of light emitted from the first pixel PXL1 and the second pixel PXL2 may be improved, and excellent color reproducibility may be secured. Manufacturing efficiency of the display device may be increased, by configuring the light emitting unit EMU of the first to third pixels PXL1, PXL2, and PXL3 using the light emitting elements LD of the same color (for example, the blue light emitting element).

The scattering layer LSL may be provided to efficiently use the light of the third color (or blue) emitted from the light emitting element LD. For example, when the light emitting element LD is the blue light emitting element emitting the blue light and the third pixel PXL3 is the blue pixel, the scattering layer LSL may include at least one type of scatterer SCT in order to efficiently use the light emitted from the light emitting element LD. For example, the scatterer SCT of the scattering layer LSL may include at least one selected from among titanium oxide (TiO2), barium sulfate (BaSO4), calcium carbonate (CaCO3), silicon oxide (SiO2), silicon nitride (Si3N4), aluminum oxide (A12O3), zirconium oxide (ZrO2), and/or zinc oxide (ZnO).

In one or more embodiments, the scatterer SCT may also be disposed in an area in addition to the third pixel PXL3, and may be selectively included in the first color conversion layer CCL1 or the second color conversion layer CCL2. According to one or more embodiments, the scatterer SCT may be omitted and the scattering layer LSL formed of a transparent polymer may be provided.

A first capping layer CPL1 may be disposed on the color conversion layer CCL. The first capping layer CPL1 may be provided over the first to third pixels PXL1, PXL2, and PXL3. The first capping layer CPL1 may cover the color conversion layer CCL. The first capping layer CPL1 may prevent an impurity such as moisture or air from permeating from the outside and damaging or contaminating the color conversion layer CCL.

The first capping layer CPL1 may be an inorganic layer, and may include one or more selected from among silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), and/or the like.

The optical layer OPL may be disposed on the first capping layer CPL1. The optical layer OPL may serve to improve light extraction efficiency by recycling light provided from the color conversion layer CCL by total reflection. To this end, the optical layer OPL may have a relatively low refractive index compared to the color conversion layer CCL. For example, the refractive index of the color conversion layer CCL may be about 1.6 to 2.0, and the refractive index of the optical layer OPL may be about 1.1 to 1.3.

A second capping layer CPL2 may be disposed on the optical layer OPL. The second capping layer CPL2 may be provided over the first to third pixels PXL1, PXL2, and PXL3. The second capping layer CPL2 may cover the optical layer OPL. The second capping layer CPL2 may prevent an impurity such as moisture or air from permeating from the outside and damaging or contaminating the optical layer OPL.

The second capping layer CPL2 may be an inorganic layer, and may include one or more selected from among silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), and/or the like.

A planarization layer PLL may be disposed on the second capping layer CPL2. The planarization layer PLL may be provided over the first to third pixels PXL1, PXL2, and PXL3. The planarization layer PLL may include an organic material such as an acrylates resin, an epoxy resin, a phenolic resin, a polyamides resin, a polyimides resin, a polyesters resin, a polyphenylenesulfides resin, or benzocyclobutene (BCB). However, the present disclosure is not necessarily limited thereto, and the planarization layer PLL may include various types of inorganic materials selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

The color filter layer CFL may be disposed on the planarization layer PLL. The color filter layer CFL may include color filters CF1, CF2, and CF3 matching the colors of each pixel PXL. As the color filters CF1, CF2, and CF3 matching the colors of each of the first to third pixels PXL1, PXL2, and PXL3 are disposed, the full-color image may be displayed.

The color filter layer CFL may include a first color filter CF1 disposed in the first pixel PXL1 to selectively transmit light emitted from the first pixel PXL1, a second color filter CF2 disposed in the second pixel PXL2 to selectively transmit light emitted from the second pixel PXL2, and a third color filter CF3 disposed in the third pixel PXL3 to selectively transmit light emitted from the third pixel PXL3.

In one or more embodiments, the first color filter CF1, the second color filter CF2, and the third color filter CF3 may be a red color filter, a green color filter, and a blue color filter, respectively, but are not limited thereto. Hereinafter, when any color filter from among the first color filter CF1, the second color filter CF2, and the third color filter CF3 is refer to, or two or more types of color filters are collectively referred to, the any color filter or the two or more types of color filters is referred to as a “color filter CF” or “color filters CF”.

The first color filter CF1 may overlap the first color conversion layer CCL1 in the third direction (Z-axis direction). The first color filter CF1 may include a color filter material that selectively transmits the light of the first color (or red). For example, when the first pixel PXL1 is the red pixel, the first color filter CF1 may include a red color filter material.

The second color filter CF2 may overlap the second color conversion layer CCL2 in the third direction (Z-axis direction). The second color filter CF2 may include a color filter material that selectively transmits the light of the second color (or green). For example, when the second pixel PXL2 is the green pixel, the second color filter CF2 may include a green color filter material.

The third color filter CF3 may overlap the scattering layer LSL in the third direction (Z-axis direction). The third color filter CF3 may include a color filter material that selectively transmits the light of the third color (or blue). For example, when the third pixel PXL3 is the blue pixel, the third color filter CF3 may include a blue color filter material.

A light blocking layer BM may be disposed on the color conversion layer CCL. The light blocking layer BM may be disposed between the first to third pixels PXL1, PXL2, and PXL3, and may at least partially overlap each of the first to third pixels PXL1, PXL2, and PXL3. The light blocking layer BM may prevent a color mixture defect visually recognized from a front or side of the display device. A material of the light blocking layer BM is not particularly limited, and may be formed of various light blocking materials. According to one or more embodiments, the light blocking layer BM may be implemented by stacking the first to third color filters CF1, CF2, and CF3 on each other, but is not necessarily limited thereto.

An overcoat layer OC may be disposed on the color filter layer CFL and the light blocking layer BM. The overcoat layer OC may be provided over the first to third pixels PXL1, PXL2, and PXL3. The overcoat layer OC may cover a lower member including the color filter layer CFL. The overcoat layer OC may prevent moisture or air from permeating into the above-described lower member. The overcoat layer OC may protect the above-described lower member from a foreign substance such as dust.

The overcoat layer OC may include an organic material such as an acrylates resin, an epoxy resin, a phenolic resin, a polyamides resin, a polyimides resin, a polyesters resin, a polyphenylenesulfides resin, and/or benzocyclobutene (BCB). However, the present disclosure is not necessarily limited thereto, and the overcoat layer OC may include various types of inorganic materials including one or more selected from among silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and/or titanium oxide (TiOx).

Those skilled in the art may understand that the present disclosure may be implemented in a modified form without departing from the above-described essential characteristic. Therefore, the disclosed methods should be considered in a description point of view not a limitation point of view. The scope of the present disclosure is shown in the claims not in the above description, and all differences within the scope will be construed as being included in the present disclosure.

What is claimed is:

1. A display device comprising:
signal lines;
auxiliary electrodes on the signal lines;
bank patterns on the auxiliary electrodes and spaced from each other;
alignment electrodes on the bank patterns and spaced from each other; and
light emitting elements between the bank patterns,
wherein the alignment electrodes are electrically connected to the auxiliary electrodes through a contact hole passing through the bank patterns, respectively, and
wherein the auxiliary electrodes and the alignment electrodes are insulated from the signal lines.

2. The display device according to claim 1, further comprising:
a first insulating layer between the auxiliary electrodes and the bank patterns.

3. The display device according to claim 2, wherein the bank patterns and the first insulating layer have a same shape on a plane.

4. The display device according to claim 2, further comprising:
a second insulating layer between the alignment electrodes and the light emitting elements.

5. The display device according to claim 4, further comprising:
a hole passing through the first insulating layer and the second insulating layer.

6. The display device according to claim 1, further comprising:
an emission area, the light emitting elements being located in the emission area;
a non-emission area surrounding the emission area; and
a bank in the non-emission area and including an opening exposing the emission area.

7. The display device according to claim 6, wherein the auxiliary electrodes overlap the bank.

8. The display device according to claim 6, wherein the alignment electrodes include a first area overlapping the auxiliary electrodes and a second area crossing the auxiliary electrodes in the non-emission area.

9. The display device according to claim 1, further comprising:
connection electrodes on the light emitting elements and electrically connected to the signal lines.

10. The display device according to claim 9, wherein the connection electrodes comprise a first connection electrode contacting a first end of the light emitting elements and a second connection electrode contacting a second end of the light emitting elements.

11. A display device comprising:
signal lines;
auxiliary electrodes extending in a first direction on the signal lines;
alignment electrodes including a first area overlapping the auxiliary electrodes and extending in the first direction and a second area extending in a second direction crossing the first direction; and
light emitting elements between the alignment electrodes,
wherein the second area of the alignment electrodes contacts the auxiliary electrodes through a contact hole, and
wherein the auxiliary electrodes and the alignment electrodes are insulated from the signal lines.

12. The display device according to claim 11, further comprising:
an emission area, the light emitting elements being located in the emission area;
a non-emission area surrounding the emission area; and
a bank in the non-emission area and including an opening exposing the emission area.

13. The display device according to claim 12, wherein the auxiliary electrodes overlap the bank.

14. The display device according to claim 12, wherein the first area of the alignment electrodes overlaps the emission area.

15. The display device according to claim 12, wherein the second area of the alignment electrodes is in the non-emission area.

16. The display device according to claim 11, further comprising:
bank patterns located between the auxiliary electrodes and the alignment electrodes.

17. The display device according to claim 16, wherein the bank patterns extend in the first direction.

18. The display device according to claim 16, wherein the contact hole is formed in the bank patterns.

19. The display device according to claim 11, further comprising:
connection electrodes on the light emitting elements and electrically connected to the signal lines.

20. The display device according to claim 19, wherein the connection electrodes comprise a first connection electrode contacting a first end of the light emitting elements and a second connection electrode contacting a second end of the light emitting elements.
